(19) United States
(12) Patent Application Publication
(10) Pub. No.: US 2018/0291524 A1
(43) Pub. Date: Oct. 11, 2018

(54) METHODS FOR PRODUCING SINGLE CRYSTAL INGOTS DOPED WITH VOLATILE DOPANTS

(71) Applicant: Corner Star Limited, Kowloon (HK)

(72) Inventors: Soubir Basak, Chandler, AZ (US); Gaurab Samanta, Brentwood, MO (US); Salvador Zepeda, St. Peters, MO (US); Christopher V. Luers, O'Fallon, MO (US); Steven L. Kimbel, St. Charles, MO (US); Carissima Marie Hudson, St. Charles, MO (US); Hariprasad Sreedharamurthy, Ballwin, MO (US); Roberto Scala, Merano (IT); Richard J. Phillips, St. Peters, MO (US); Tirumani N. Swaminathan, Creve Coeur, MO (US); Jihong Chen, Cincinnati, OH (US); Stephen Wayne Palmore, Vancouver, WA (US); Peter Drury Wildes, Washougal, WA (US)

(21) Appl. No.: 15/570,955

(22) PCT Filed: Apr. 29, 2016
(86) PCT No.: PCT/US2016/030209

§ 371 Date: Oct. 31, 2017

Related U.S. Application Data
(60) Provisional application No. 62/155,661, filed on May 1, 2015.

(51) Int. Cl. C30B 15/04; C30B 29/06; C30B 15/20

(52) U.S. Cl. CPC C30B 15/04; C30B 15/20; C30B 29/06

(57) ABSTRACT

Methods for growing single crystal ingots doped with volatile dopants and ingots grown according to the methods are described herein.

### CROSS REFERENCE TO RELATED APPLICATION

This application claims priority to U.S. Provisional Application Ser. No. 62/155,661, filed May 1, 2015, the disclosure of which is incorporated by reference in its entirety.

### FIELD

The field of the disclosure relates generally to methods for producing ingots of semiconductor or solar material from a melt and, more particularly, to methods for producing single crystal ingots of semiconductor or solar material doped with volatile dopants and having uniform axial resistivity profiles.

### BACKGROUND

In the production of silicon crystals grown by the continuous Czochralski (CCZ) method, polycrystalline silicon is first melted within a crucible, such as a quartz crucible, of a crystal pulling device to form a silicon melt. The puller then lowers a seed crystal into the melt and slowly raises the seed crystal out of the melt. As the seed crystal is grown from the melt, solid polysilicon or liquid silicon is continuously added to the melt to replenish the silicon that is incorporated into the growing crystal.

Suitable amounts of dopants are continuously added to the melt to modify the base resistivity of the resulting monocrystalline ingot. In some instances, volatile dopants are used in the silicon crystal growth process. Moreover, in some applications, relatively large amounts of dopants are used to obtain a relatively low resistivity in the monocrystalline ingot.

Doping a melt with a volatile dopant may present several challenges to producing single crystal ingots using the continuous Czochralski growth method. For example, when volatile dopants are used to dope a melt, a significant portion of the dopant may evaporate from the melt. Such dopant evaporation, if not properly accounted for, can result in significant variations in the dopant concentration of the melt over time, and result in an ingot having a non-uniform axial resistivity profile. While some models have been developed to predict dopant concentration in a melt, the accuracy of such models can be improved by more accurately accounting for different mechanisms of dopant transport during a CCZ growth process.

Additionally, use of volatile dopants may enhance the evaporation of oxygen species from the melt as dopant oxides and suboxides, in addition to oxides and suboxides of silicon, which may condense and deposit on components of the crystal growing system. These deposits can form on view ports of crystal growing systems, typically located on an upper dome of such systems, and impede an operator's ability to monitor the crystal growth process. Also, particulate deposits may subsequently fall into the melt during the ingot growth process, and result in particulate induced loss of structure or zero dislocation growth and failure of a CCZ batch.

Accordingly, a need exists for a more efficient method that enables the production of multiple semiconductor or solar grade single crystal ingots having uniform axial resistivity profiles from a single batch using the CCZ method.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a method of growing a single crystal ingot from a melt of semiconductor or solar material is provided. The melt includes an inner melt zone separated from an outer melt zone by one or more fluid barriers. The method includes contacting the melt with a seed crystal within the inner melt zone to initiate crystal growth, pulling the seed crystal away from the melt to grow a single crystal ingot, the ingot having a crown region, a neck region, a shoulder region, and a body region, growing the ingot such that the body region has an axial length of at least 1,000 mm, and controlling a dopant concentration of the inner melt zone such that the resistivity over at least 500 mm of the axial length of the ingot varies by no more than 15%. Controlling the dopant concentration of the inner melt zone includes using a model to predict the dopant concentration of the melt in the inner melt zone based at least in part on diffusion of the dopant between the inner melt zone and the outer melt zone.

In another aspect, a method of growing a single crystal ingot from a melt of semiconductor or solar material is provided. The melt includes an inner melt zone separated from an outer melt zone by one or more fluid barriers. The method includes determining a target resistivity for an ingot, contacting the melt with a seed crystal within the inner melt zone to initiate crystal growth, pulling the seed crystal away from the melt to grow a single crystal ingot, calculating an initial amount of dopant to be added to the melt based on the target resistivity, and adding the initial amount of dopant to the outer melt zone. Calculating the initial amount of dopant includes using a model to predict a dopant concentration of the melt in the inner melt zone based at least in part on diffusion of the dopant between the inner melt zone and the outer melt zone.

In yet another aspect, a single crystal silicon ingot grown by a continuous Czochralski method is provided. The singly crystal silicon ingot includes a constant diameter region, an axial length as measured from a seed end of the constant diameter region to a terminal end of the constant diameter region, and an electrically active dopant selected from the group consisting of arsenic, antimony, red phosphorous, and indium. The axial length of the constant diameter region is at least 1,000 mm long, and the resistivity over at least 500 mm of the axial length varies by no more than 15%.

In yet another aspect, a single crystal silicon ingot grown by a continuous Czochralski method is provided. The single crystal silicon ingot includes a constant diameter region, an axial length as measured from a seed end of the constant diameter region to a terminal end of the constant diameter region, and an electrically active dopant. The axial length of the constant diameter region is at least 1,500 mm long, and the resistivity over at least 1,000 mm of the axial length varies by no more than 10%.

In yet another aspect, a method of growing a single crystal ingot from a melt of semiconductor or solar material within a growth chamber is provided. The method includes introducing a carrier gas into the growth chamber such that the carrier gas flows across a surface of the melt, the carrier gas having an inlet flow rate and a localized flow rate across the surface of the melt, growing a single crystal ingot from the melt, controlling an operating pressure within the growth chamber at a first operating pressure while the ingot is being grown, removing the ingot from the growth chamber, and controlling particulate deposition on components within the growth chamber by controlling the operating pressure at a second operating pressure less than the first operating pressure while the ingot is being removed from the growth chamber. Controlling the operating pressure at the second operating pressure causes the localized flow rate of the carrier gas to increase.

In yet another aspect, a method of growing a single crystal ingot from a melt of semiconductor or solar material within a growth chamber is provided. The method includes introducing a carrier gas into the growth chamber such that the carrier gas flows across a surface of the melt, the carrier gas having an inlet flow rate and a localized flow rate across the surface of the melt, growing a single crystal ingot from the melt, controlling the inlet flow rate of the carrier gas at a first inlet flow rate while the ingot is being grown, removing the ingot from the growth chamber, and controlling particulate deposition on components within the growth chamber by controlling the inlet flow rate of the carrier gas at a second inlet flow rate greater than the first inlet flow rate while the ingot is being removed from the growth chamber. Controlling the inlet flow rate at the second inlet flow rate causes the localized flow rate of the carrier gas to increase.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a cross-section of an example crystal growing system;

FIG. 2 is a schematic representation of a crystal growing system illustrating different transport mechanisms of a dopant during a continuous Czochralski growth process;

FIG. 3 is a flow chart of an example method of growing a single crystal ingot from a melt of semiconductor or solar material;

FIG. 4 is a flow chart of another example method of growing a single crystal ingot from a melt of semiconductor or solar material;

FIG. 5 is a flow chart of another example method of growing a single crystal ingot from a melt of semiconductor or solar material;

FIG. 6 is a partial cross-section of a crystal growing system illustrating computer simulated flow streamlines of a carrier gas flowing through the crystal growing system while a crystal ingot is being grown;

FIG. 7 is a partial cross-section of the crystal growing system of FIG. 6 illustrating computer simulated flow streamlines of a carrier gas flowing through the crystal growing system after the crystal ingot is removed from the crystal growing system;

FIG. 8 is a graph illustrating SiO deposition rates on a dome of the crystal growing system of FIG. 6 at a constant gas inlet flow rate and various operating pressures;

FIG. 9 is an enlarged view of the crystal growing system of FIG. 6 illustrating velocity vector plots of a carrier gas near the surface of a melt contained within the crystal growing system at an operating pressure of 65 Torr;

FIG. 10 is an enlarged view of the crystal growing system of FIG. 6 illustrating velocity vector plots of a carrier gas near the surface of the melt at an operating pressure of 30 Torr;

FIG. 11 is a graph illustrating SiO deposition rates on the dome of the crystal growing system of FIG. 6 at a constant operating pressure and various gas inlet flow rates;

FIG. 12 is a flow chart of an example method of growing a single crystal ingot from a melt of semiconductor or solar material;

FIG. 13 is a flow chart of another example method of growing a single crystal ingot from a melt of semiconductor or solar material;

FIG. 14 is a perspective view of a single crystal silicon ingot grown by a continuous Czochralski method;

FIG. 15 is a plot of measured resistivity values from two antimony-doped monocrystalline ingots grown by a continuous Czochralski method;

FIG. 16 is a plot of measured resistivity values from another antimony-doped monocrystalline ingot grown by a continuous Czochralski method;

FIG. 17 is a plot of measured resistivity values from an arsenic-doped monocrystalline ingot grown by a continuous Czochralski method;

FIG. 18 is a plot of measured resistivity values from an indium-doped monocrystalline ingot grown by a continuous Czochralski method;

FIG. 19 is a plot of measured resistivity values from another indium-doped monocrystalline ingot grown by a continuous Czochralski method;

FIG. 20 is a plot of measured resistivity values from another indium-doped monocrystalline ingot grown by a continuous Czochralski method;

FIG. 21 is a plot of measured resistivity values from another indium-doped monocrystalline ingot grown by a continuous Czochralski method; and

FIGS. 22-24 are photographs of the upper dome from crystal growing systems in which continuous Czochralski growth processes were carried out under different operating pressures and gas inlet flow rates.

Corresponding reference characters indicate corresponding parts throughout the several views of the drawings.

### DETAILED DESCRIPTION

The Czochralski growth methods described herein enable the production of multiple, single crystal semiconductor and solar grade ingots that are doped with one or more volatile dopants, such as antimony, arsenic, red phosphorous, gallium, and indium, from a single continuous batch. In particular, the present disclosure provides methods for controlling the axial resistivity profile of ingots grown by the CCZ method using a model to predict dopant concentration of the growth zone of a melt at any point during the CCZ process. Additionally, the present disclosure provides methods that facilitate reducing or eliminating the high resistivity transient region typically found in semiconductor or solar grade crystals doped with highly volatile dopants. The present disclosure also provides methods for controlling and reducing deposits of evaporated oxides and other volatile species on crystal growing parts during the CCZ process. As used herein, the term “volatile dopant” generally refers to dopants that have a tendency to evaporate when introduced into a melt of semiconductor or solar grade material. Examples of volatile dopants include, for example and without limitation, arsenic, antimony, red phosphorous, indium, and gallium.

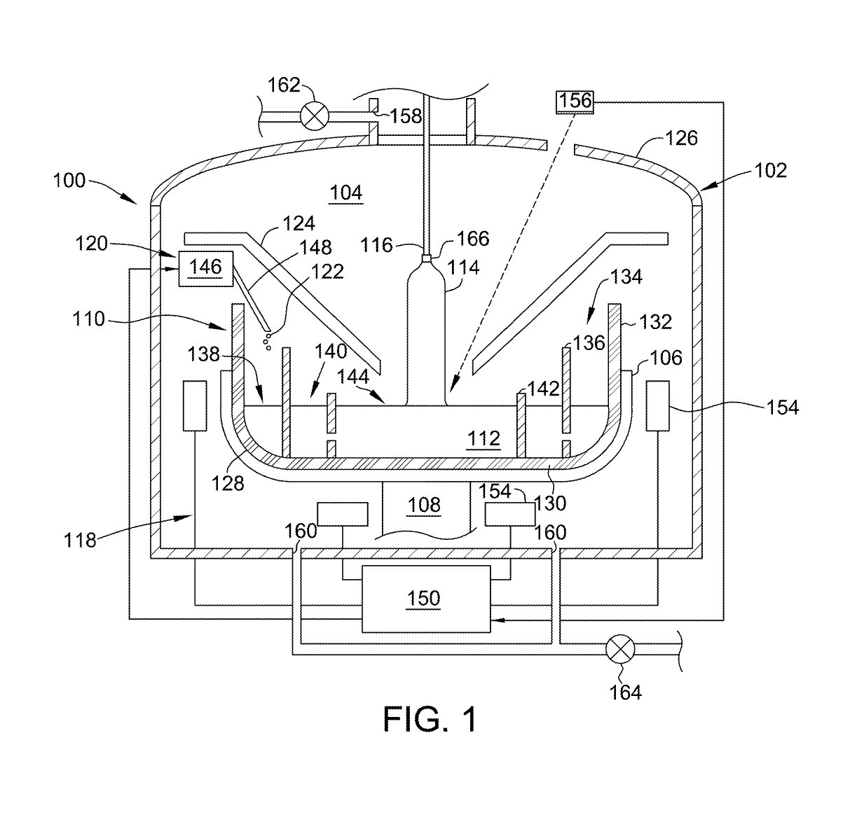

Referring to FIG. 1, one suitable apparatus for carrying out the methods described herein is shown schematically in the form of a crystal growing system, and is indicated generally at 100.

The illustrated crystal growing system 100 includes a housing 102 defining a growth chamber 104, a susceptor 106 supported by a rotatable shaft 108, a crucible assembly 110 that contains a melt 112 of semiconductor or solar grade material (e.g., silicon) from which an ingot 114 is being pulled by a crystal puller 116, and a heating system 118 for supplying thermal energy to the system 100. The illustrated system 100 also includes a feed system 120 for feeding solid or liquid feedstock material 122 and dopants into the crucible assembly 110 and/or the melt 112, and a heat shield 124 configured to shield the ingot 114 from radiant heat from the melt 112 to allow the ingot 114 to solidify.

The housing 102 encloses the susceptor 106, the crucible assembly 110, and portions of the heating system 118 within the growth chamber 104. The housing 102 includes an upper dome 126, which may include one or more view ports to enable an operator to monitor the growth process. In use, the housing 102 may be used to seal the growth chamber 104 from the external environment. Suitable materials from which the housing 102 may be constructed include, but are not limited to, stainless steel.

The crucible assembly 110 includes a crucible 128 having a base 130 and a generally annular sidewall 132 extending around the circumference of the base 130. Together, the base 130 and the sidewall 132 define a cavity 134 of the crucible 128 within which the melt 112 is disposed. The crucible 128 may be constructed of any suitable material that enables the system 100 to function as described herein including, for example, quartz.

The crucible assembly 110 also includes a plurality of weirs or fluid barriers that separate the melt 112 into different melt zones. In the illustrated embodiment, the crucible assembly 110 includes a first weir 136 (broadly, a fluid barrier) separating an outer melt zone 138 of the melt 112 from an inner melt zone 140 of the melt 112, and a second weir 142 (broadly, a fluid barrier) at least partially defining a growth zone 144 from which the crystal ingot 114 is pulled. The first weir 136 and the second weir 142 each have a generally annular shape, and have at least one opening defined therein to permit the melt 112 to flow radially inward towards the growth zone 144. The first weir 136 and the second weir 142 are disposed within the cavity 134 of the crucible 128, and create a circuitous path from the outer melt zone 138 to the inner melt zone 140 and the growth zone 144. The weirs 136, 142 thereby facilitate melting solid feedstock material 122 before it reaches an area immediately adjacent to the growing crystal (e.g., the growth zone 144). The weirs 136, 142 may be constructed from any suitable material that enables the system 100 to function as described herein, including, for example, quartz. While the illustrated embodiment is shown and described as including two weirs, the system 100 may include any suitable number of weirs that enables the system 100 to function as described herein, such as one weir, three weirs, or four or more weirs.

The crucible 128, the first weir 136, and the second weir 142 may be formed separately from one another, and assembled to form the crucible assembly 110. In other suitable embodiments, the crucible assembly 110 may have a unitary construction. That is, the crucible 128 and one or both weirs 136, 142 may be integrally formed (e.g., formed from a unitary piece of quartz).

The feed system 120 includes a feeder 146 and a feed tube 148. Feedstock material 122 and/or dopant material may be placed into the outer melt zone 138 from the feeder 146 through the feed tube 148 to replenish the melt 112 and maintain a desired dopant concentration in the melt 112. The amount of feedstock material 122 and dopant added to the melt 112 may be controlled by a controller (such as the controller 150, described below). In the illustrated embodiment, a single feed system 120 is used to feed both feedstock material 122 and dopant material into the melt 112. In other embodiments, separate feed systems may be employed to feed feedstock material 122 and dopant material into the melt 112. The feedstock material 122 supplied to the outer melt zone 138 may be solid or liquid. In some embodiments, the feedstock material 122 is polycrystalline silicon.

The heat shield 124 is positioned adjacent the crucible assembly 110, and separates the melt 112 from an upper portion of the system 100. The heat shield 124 is configured to shield the ingot 114 from radiant heat generated by the melt 112 and the heating system 118 to allow the ingot 114 to solidify. In the example embodiment, the heat shield 124 includes a conical member separating the melt 112 from an upper portion of the system 100, and a central opening defined therein to allow the ingot 114 to be pulled therethrough. In other embodiments, the heat shield 124 may have any suitable configuration that enables the system 100 to function as described herein. In the example embodiment, the heat shield 124 is constructed from graphite. In other embodiments, the heat shield 124 may be constructed from any suitable material that enables the system 100 to function as described herein, including, for example, silica-coated graphite, high purity molybdenum, and combinations thereof.

The heating system 118 is configured to melt an initial charge of solid feedstock material (such as chunk polysilicon), and maintain the melt 112 in a liquefied state after the initial charge is melted. The heating system 118 includes a plurality of heaters 154 arranged at suitable positions about the crucible assembly 110. In the illustrated embodiment, each heater 154 has a generally annular shape. The illustrated heating system 118 includes two heaters 154. One heater is positioned beneath the crucible 128 and the susceptor 106, and one heater is positioned around and radially outward of the sidewall 132 of the crucible 128.

In the example embodiment, the heaters 154 are resistive heaters, although the heaters 154 may be any suitable heating device that enables the system 100 to function as described herein. Further, while the illustrated embodiment is shown and described as including two heaters 154, the system 100 may include any suitable number of heaters 154 that enables the system 100 to function as described herein.

The heaters 154 are connected to the controller 150, which controls the electric energy provided to the heaters 154 to control the amount of thermal energy supplied by the heaters 154. The amount of current supplied to each of the heaters 154 by the controller 150 may be separately and independently controlled to optimize the thermal characteristics of the melt 112. In the illustrated embodiment, the controller 150 also controls feed system 120 and the delivery of feedstock material 122 to the melt 112 to control the temperature of the melt 112.

A sensor 156, such as a pyrometer or similar temperature sensor, provides a continuous measurement of the temperature of the melt 112 at the crystal/melt interface of the growing single crystal ingot 114. Sensor 156 also may be configured to measure the temperature of the growing ingot 114. Sensor 156 is communicatively coupled with controller 150. While a single communication lead is shown for clarity, one or more temperature sensor(s) may be linked to the controller 150 by multiple leads or a wireless connection, such as by an infra-red data link or another suitable means.

During a Czochralski growth process, a carrier gas may be introduced into the growth chamber 104 through one or more gas inlets 158 to remove evaporated species and particulates from the growth chamber 104. Gas introduced through the gas inlets 158 is exhausted through one or more exhaust outlets 160.

The gas inlets 158 are connected in fluid communication with a suitable inert gas source (not shown). Suitable inert gasses include, for example and without limitation, argon, helium, nitrogen, neon, and combinations thereof. Gas introduced through the gas inlets 158 flows generally downward within the growth chamber 104, and across the surface of the melt 112. The flow rate of gas through the gas inlet 158 (i.e., the inlet flow rate) may be controlled using one or more flow controllers 162. The flow controllers 162 may include any suitable device or combination of devices that enables the crystal growing system 100 to function as described herein including, for example and without limitation, mass flow controllers, volumetric flow controllers, throttle valves, and butterfly valves.

Gas introduced through gas inlets 158 is exhausted through exhaust outlets 160. The exhaust outlets 160 may be connected to an exhaust fan or pump (not shown) to remove inert gases from the growth chamber, along with evaporated species and particulates carried by the inert gas. The exhaust outlets 160 are also connected in fluid communication with a pressure controller 164 configured to control an operating pressure within the growth chamber 104 during a growth process. The pressure controller 164 may include any suitable device or combination of devices that enable the crystal growing system to function as described herein including, for example and without limitation, electronic pressure controllers, throttle valves, butterfly valves, ball valves, pumps, and fans. The pressure controller 164 may be operated independent of or in conjunction with an exhaust fan or pump connected to the exhaust outlets.

The localized flow rate of gas across the surface of the melt 112 may vary from the inlet flow rate due to varying sizes of gas flow passages defined between the melt surface and components of the crystal growing system 100, such as the heat shield 124. As described in more detail herein, the localized gas flow rate across the surface of the melt 112 may be controlled by adjusting the operating pressure within the growth chamber 104 and/or the inlet flow rate of the carrier gas.

During the continuous Czochralski growing process, an initial charge of semiconductor or solar material, such as silicon, is melted in the crucible 128. A desired type and amount of dopant is added to the melt 112 to modify the base resistivity of the resulting ingot 114. A seed crystal 166 connected to the crystal puller 116 is lowered into contact with the melt 112, and then slowly raised from the melt 112. As the seed crystal 166 is slowly raised from the melt 112, atoms from the melt 112 align themselves with and attach to the seed crystal 166 to form the ingot 114. Feedstock material 122 and additional dopant is added to melt 112 while the ingot 114 is pulled from the melt 112 to replenish the melt 112 and maintain the desired dopant concentration in the melt 112.

The resistivity of the ingot 114 is inversely related to dopant concentration of the ingot 114, which is directly related to the dopant concentration of the inner melt zone from which the ingot is grown. Maintaining the dopant concentration of the inner melt zone near a target concentration during the ingot growing process is desirable to obtain an ingot with a substantially uniform axial resistivity. For certain applications, it is desirable that the ingot have a relatively low resistivity, such as no more than 30 milliohm-centimeters (mΩ-cm), no more than 20 mΩ-cm, no more than 10 mΩ-cm, no more than 3 mΩ-cm, or even no more than 2 mΩ-cm. Obtaining ingots with such low resistivities requires the melt from which the ingots are grown to have a high dopant concentration. Further, for some applications, it is desirable that the ingot be doped with certain dopants that are relatively volatile when used in the continuous Czochralski growth process. Relatively volatile dopants include, for example and without limitation, indium, antimony, arsenic, gallium, and red phosphorous.

Doping a melt with a volatile dopant may present several challenges to producing single crystal ingots using the continuous Czochralski growth method. In particular, when volatile dopants are used to dope a melt, a significant portion of the dopant may evaporate from the melt. Such dopant evaporation, if not properly accounted for, can result in significant variations in the dopant concentration of the melt over time, and result in an ingot having a non-uniform axial resistivity profile. Additionally, use of volatile dopants may enhance the evaporation of oxide species (e.g., SiO and SiO₂) from the melt along with evaporation of oxide and suboxides of the dopant, which may condense and deposit on components of the crystal growing system. These deposits may subsequently fall into the melt during the ingot growth process, and result in a particulate induced loss of structure or zero dislocation growth. The methods described herein address the above-noted issues with doping a melt with a volatile dopant.

In one aspect, the present disclosure provides a method of controlling the dopant concentration within the inner melt zone using a model to predict the dopant concentration within the inner melt zone during the Czochralski growth process. In particular, a model is provided to account for the numerous dopant transport mechanisms that affect the dopant concentration within different melt zones of a melt over the course of a Czochralski growth process. The transport mechanisms affecting dopant concentration within the melt include dopant evaporation, convective mass transport between adjacent melt zones, diffusion between adjacent melt zones resulting from dopant concentration gradients, and dopant segregation from the ingot being grown. Also affecting dopant concentration is additional dopant and melt material added to the melt throughout the Czochralski growth process.

By accounting for each of the above-described transport mechanisms, the evolution of dopant concentration within each melt zone over time can be expressed using the following generalized differential equation:

$$\frac{{dN}_{i} ( t )}{dt} = - {k}_{eff} ( \dot{v} , CR , XR ) \dot{v} ( t ) \frac{{N}_{i} ( t )}{{V}_{i}} + fr ( t ) + {D}_{i , i + 1} ( t ) {A}_{i , i + 1} \frac{\frac{{N}_{i + 1} ( t )}{{V}_{i + 1}} - \frac{{N}_{i} ( t )}{{V}_{i}}}{{I}_{i , i + 1}} - {D}_{i - 1 , i} ( t ) {A}_{i - 1 , i} \frac{\frac{{N}_{i} ( t )}{{V}_{i}} - \frac{{N}_{i - 1} ( t )}{{V}_{i - 1}}}{{I}_{i - 1 , i}} - \dot{v} ( t ) \frac{{N}_{i} ( t )}{{V}_{i}} + \dot{v} ( t ) \frac{{N}_{i + 1} ( t )}{{V}_{i + 1}} - g ( P , L , HR , CR , XR , t ) SA ( t ) \frac{{N}_{i} ( t )}{{V}_{i}} \qquad Eq . 1$$

where Nᵢ represents the number of dopant atoms in the i^{th} melt zone of a crystal growing system, t represents the elapsed time from a reference point, such as the time at which crystal growth is initiated or the time at which an initial amount of dopant is added to the melt, k_{eff} represents the effective segregation coefficient of the dopant, which is dependent upon the pull speed (\dot{ν}) of the crystal ingot, the rotation rate of the crucible (CR), and the rotation rate of the crystal ingot (XR), \dot{ν}(t) represents the volumetric flow rate of melt material between melt zones calculated from the ingot pull speed, Vᵢ represents the volume of the melt in the i^{th} melt zone, fr(t) represents the feed rate of dopant into the i^{th} melt zone, D represents the diffusion coefficient (also referred to as a mass transfer coefficient) between adjacent melt zones, A represents the total cross-sectional area of the openings in the fluid barrier between adjacent melt zones, l represents the length of the openings in the fluid barrier between adjacent melt zones, g represents the evaporation coefficient, which is dependent upon the pressure within the crystal pulling system (P), the gas flow rate across the melt surface (L), the spacing between the heat shield and the surface of the melt (HR), the rotation rate of the crucible (CR), the rotation rate of the crystal ingot (XR), and time (t), and SA(t) represents the exposed surface area of the melt zone. In Equation 1, subscripts are used to denote the various melt zones of the crystal growing system, where i+1 indicates the melt zone located adjacent to and radially inward from the i^{th} melt zone, and i−1 represents the melt zone located adjacent to and radially outward from the i^{th} melt zone.

The coefficient terms of Equation 1 (i.e., the segregation coefficient, the diffusion coefficients, and the evaporation coefficient) may also exhibit a dependence upon the setup or geometry of the specific crystal growing system used to grow a crystal ingot. Accordingly, in some embodiments, the segregation coefficient, the diffusion coefficients, and the evaporation coefficient are empirically determined for a specific crystal growing system based on one more Czochralski growth procedures carried out in the crystal growing system. Further, in some embodiments, separate models may be developed for the crystal growing system to approximate one or more of the segregation coefficient, the diffusion coefficients, and the evaporation coefficient as a function of one or more variables, such as crystal ingot pull rate, the pressure within the crystal growing system, the crucible rotation rate, the crystal ingot rotation rate, and the gas flow rate across the melt surface.

As indicated in Equation 1, the dopant concentration of each melt zone is dependent on the dopant concentration of adjoining melt zones. For a given crystal growing system having a determinate number of melt zones, Equation 1 can be used to establish a model that predicts the dopant concentration in each melt zone over the course of a continuous Czochralski method. In particular, applying Equation 1 to each melt zone provides a set of differential equations, one for each melt zone, which represents the dopant concentration in each melt zone as a function of time. The set of differential equations can be used to model and predict the dopant concentration within each melt zone of a crystal growing system over time to provide an accurate estimation of the axial resistivity profile of an ingot grown by the Czochralski method.

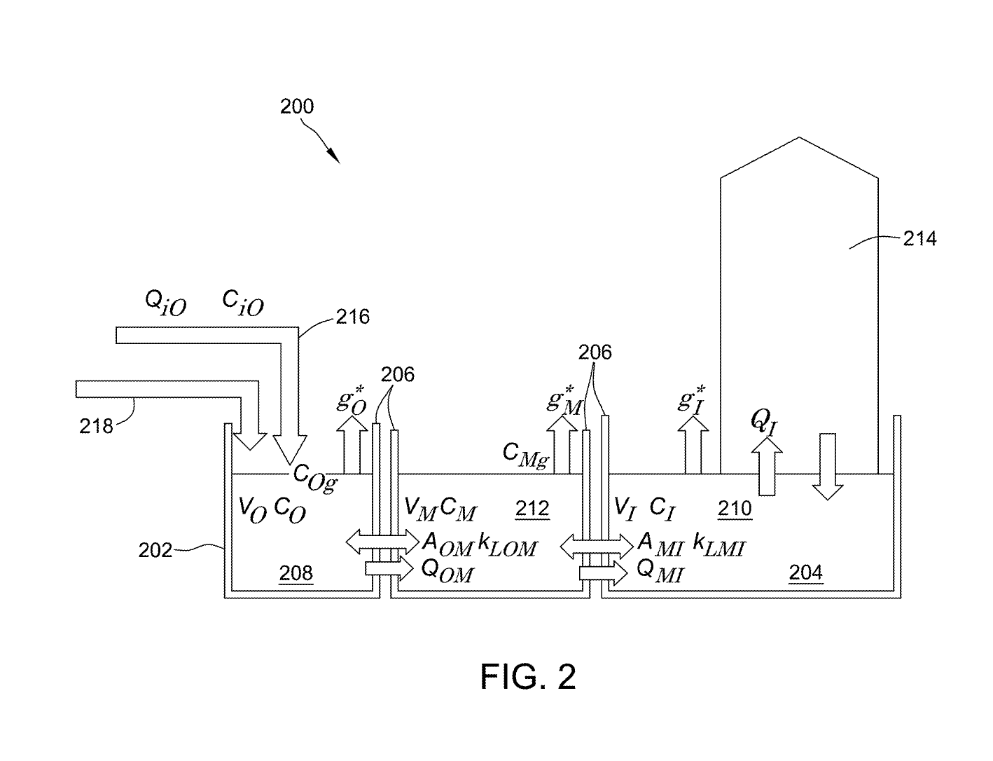

FIG. 2 is a simple schematic representation of a crystal growing system 200 illustrating the different transport mechanisms of a dopant in a three melt zone system. The crystal growing system 200 of FIG. 2 is representative of crystal growing systems having three discrete melt zones, such as the two weir crystal growing system 100 of FIG. 1. The crystal growing system 200 includes a crucible 202 having a melt 204 disposed therein, and weirs or fluid barriers 206 defining an outermost or, more generally, outer melt zone 208, an inner melt zone 210, and a middle or transition melt zone 212 between the outer melt zone 208 and the inner melt zone 210. The transition melt zone 212 may also be considered an outer melt zone relative to the inner melt zone 210. A crystal ingot 214 is grown from the inner melt zone 210 while dopant and feedstock material, indicated by arrows 216 and 218, respectively, are fed to the outer melt zone 208. In some embodiments, dopant may additionally or alternatively be added to the transition melt zone 212. The various transport mechanisms affecting the dopant concentration within the melt 204 are depicted by arrows in FIG. 2 indicating the direction of dopant transport.

Using the crystal growing system illustrated in FIG. 2 as an example, Equation 1 can be expressed as the following set of differential equations:

$$\begin{matrix}\frac{\partial ( {V}_{O} {C}_{O} )}{\partial t} = {Q}_{iO} {C}_{iO} - {Q}_{OM} {C}_{O} - {A}_{O} {g}_{O}^{*} ( {C}_{O} - {C}_{gO} ) - {A}_{OM} {k}_{LOM} ( {C}_{O} - {C}_{M} ) & Eq . 2 \\ \frac{\partial ( {V}_{M} {C}_{M} )}{\partial t} = {Q}_{OM} {C}_{O} - {Q}_{MI} {C}_{M} - {A}_{M} {g}_{M}^{*} ( {C}_{M} - {C}_{gM} ) + {A}_{OM} {k}_{LOM} ( {C}_{O} - {C}_{M} ) - {A}_{MI} {k}_{LMI} ( {C}_{M} - {C}_{I} ) & Eq . 3 \\ \frac{\partial ( {V}_{I} {C}_{I} )}{\partial t} = {Q}_{MI} {C}_{M} - {kQ}_{I} {C}_{I} - {A}_{IC} {g}_{I}^{*} ( {C}_{I} - {C}_{gI} ) + {A}_{MI} {k}_{LMI} ( {C}_{M} - {C}_{I} ) & Eq . 4\end{matrix}$$

where V represents the volume of melt within the respective melt zone, C represents the dopant concentration of the melt within the respective melt zone, t represents the elapsed time from a reference point, such as the time at which crystal growth is initiated or the time at which an initial amount of dopant is added to the melt, Q represents the volumetric flow rate between adjacent melt zones, A represents the surface area of the melt within the respective melt zone, g* represents the evaporation coefficient of the dopant within the respective melt zone, C_{g} represents the dopant concentration in the gas phase adjacent the respective melt zone, k_{L} represents the mass transfer coefficient between adjacent melt zones, and k represents the effective segregation coefficient of the dopant. In Equations 2-4, subscripts are used to denote the various melt zones of the crystal growing system, where I represents the inner melt zone 210, M represents the middle melt zone 212, and O represents the outer melt zone 208. The term Q_{iO} represents the volumetric feed rate of melt material into the outer melt zone 208, and the term C_{iO} represents the dopant concentration of the melt material being fed into the outer melt zone. Terms from Equations 2-4 are illustrated in FIG. 2 next to the arrow that corresponds to the transport mechanism with which the respective term is associated.

The concentration of dopant within the melt can be determined by solving the three coupled ordinary differential equations represented by Equations 2-4. The terms in Equations 2-4, such as the coefficient terms, may vary over time depending upon the environmental conditions and operating parameters within the crystal growing system. For example, the gas pressure and flow rate during crystal growth may be different from the gas pressure and flow rate during the period between successive crystals being grown, resulting in different evaporation coefficients. Accordingly, in some embodiments, the set of coupled ordinary differential equations are solved for multiple time periods or intervals of the Czochralski growth process.

The concentration of dopant in the crystal ingot can be determined from the dopant concentration in the melt using the equation:

C_{c}=k_{Cl} Eq. 5

where C_{c} represents the dopant concentration in the crystal ingot, k represents the effective segregation coefficient of the dopant, and Cₗ represents the dopant concentration of the inner melt zone from which the crystal ingot is grown. The resistivity of the crystal ingot can be determined based on the dopant concentration using standard conversion tables and/or formulas known in the art, such as standards SEMI MF723-0307 and SEMI F723-99, published by SEMI International Standards.

Accordingly, the above equations can be used to establish a model to predict the dopant concentration of a melt over the course of a Czochralski growth process. This model can be used to control the dopant concentration within the inner melt zone of a melt and, consequently, to control the axial resistivity profile of an ingot grown from the inner melt zone. The dopant concentration of the inner melt zone can be controlled, for example, by controlling at least one of the initial dopant concentration in one or more melt zones and the dopant feed rate in one or more melt zones based on a target dopant concentration or ingot resistivity. Additionally, the model can be used to reduce or eliminate the high resistivity transient region typically found at the seed end of semiconductor or solar grade ingots doped with highly volatile dopants.

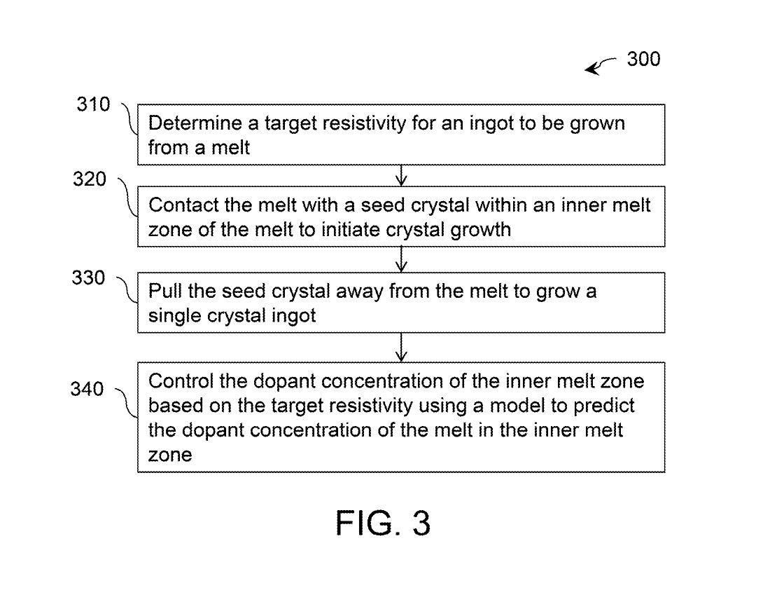

FIG. 3 is a flow chart of an example method 300 of growing a single crystal ingot from a melt of semiconductor or solar material using the above-described model. The melt includes an inner melt zone separated from an outer melt zone by one or more fluid barriers. The method 300 generally includes determining 310 a target resistivity for an ingot to be grown from the melt, contacting 320 the melt with a seed crystal within the inner melt zone to initiate crystal growth, pulling 330 the seed crystal away from the melt to grow a single crystal ingot, and controlling 340 the dopant concentration of the inner melt zone based on the target resistivity using a model to predict the dopant concentration of the melt in the inner melt zone. The model used to predict dopant concentration of the melt in the inner melt zone may be based at least in part on diffusion of the dopant between the inner melt zone and the outer melt zone, evaporation of the dopant from the melt, segregation of the dopant from the ingot being grown, and convective mass transfer between the inner melt zone and the outer melt zone.

Controlling 340 the dopant concentration of the inner melt zone generally includes at least one of adding an initial amount of dopant to the outer melt zone, and adding dopant to the outer melt zone during crystal growth according to a determined dopant feed rate. In some embodiments, the initial amount of dopant added to the outer melt zone and the dopant feed rate are calculated based on the target resistivity using the model to predict the dopant concentration of the melt in the inner melt zone.

The dopant added to the melt may include any suitable dopant material used for semiconductor and solar materials including, for example and without limitation, boron, phosphorous, indium, antimony, aluminum, arsenic, gallium, red phosphorous, and combinations thereof. The methods and models described herein are also suitable for use with group IV dopants, such as germanium. In some embodiments, the dopant added to the melt may include more than one type of dopant. For example, the dopant may include an N-type dopant and a P-type dopant. In some embodiments, the dopant includes an N-type dopant as a minority carrier, and a P-type dopant as a majority carrier. In yet other embodiments, the dopant includes an N-type dopant as a majority carrier, and a P-type dopant as a minority carrier. In some embodiments, the N-type dopant is selected from the group consisting of phosphorus, arsenic, and antimony, and the P-type dopant is selected from the group consisting of boron, aluminum, gallium and indium.

The methods and models described herein are particularly well suited for use with relatively volatile dopants. In some embodiments, for example, the dopant added to the melt in method 300 is selected from the group consisting of indium, antimony, arsenic, and red phosphorous.

In some embodiments, determining 310 the target resistivity is dependent upon the dopant added to the melt. Where the dopant is arsenic, for example, the determined target resistivity may be no more than about 3 mΩ-cm, more suitably no more than about 2 mΩ-cm, more suitably no more than about 1.6 mΩ-cm, and even more suitably, no more than about 1.5 mΩ-cm. Where the dopant is antimony, the determined target resistivity may be no more than about 30 mΩ-cm, more suitably no more than about 20 mΩ-cm, and even more suitably, no more than about 10 mΩ-cm. Where the dopant is red phosphorous, the determined target resistivity may be no more than about 1.7 mΩ-cm, more suitably no more than about 1.2 mΩ-cm, and even more suitably, no more than about 1 mΩ-cm. Where the dopant is boron, the determined target resistivity may be no more than about 3 mΩ-cm, more suitably no more than about 2 mΩ-cm, and even more suitably, no more than about 1 mΩ-cm. Where the dopant is indium, the determined target resistivity may be no more than about 5 Ω-cm, more suitably no more than about 3 Ω-cm, and even more suitably, no more than about 2 Ω-cm.

In some embodiments, the method 300 may further include determining at least one of a mass transfer coefficient for the dopant within the melt, an effective segregation coefficient of the dopant, and an evaporation coefficient of the dopant. In some embodiments, the coefficients are determined empirically based on one or more Czochralski growth processes. The coefficients may be used with the model to predict the dopant concentration of the melt in the inner melt zone, and to control the dopant concentration of the melt within the inner melt zone. In some embodiments, for example, one or both of the initial dopant amount and the dopant feed rate are calculated based on at least one of the determined mass transfer coefficient, the determined effective segregation coefficient, and the determined evaporation coefficient.

The methods and models described herein are also particularly well suited for doping melts with relatively large amounts of dopants such that ingots grown from the melt have a relatively low resistivity. In particular, the methods and models described herein facilitate maintaining a melt at or near a constitutional supercooling limit associated with a dopant and a melt temperature to achieve relatively low resistivities in ingots grown from the melt. In some embodiments, for example, dopants are added to the melt to achieve a dopant concentration in the melt of no less than about 1×10¹⁸ atoms/cm³, no less than about 1×10¹⁹ atoms/cm³, and even up to about 1×10²⁰ atoms/cm³. By providing an accurate model to predict the dopant concentration of the inner melt zone from which an ingot is grown, the dopant concentration can be maintained at or near the constitutional supercooling limit without exceeding the limit, which could result in rapid dendritic growth and loss of the single crystalline structure of the ingot. Accordingly, in some embodiments, controlling 340 the dopant concentration of the inner melt zone further includes maintaining the dopant concentration of the inner melt zone near a constitutional supercooling limit associated with the dopant and a temperature of the melt.

Ingots grown according to the method 300 may be grown along any suitable crystal growth orientation that enables the methods to be performed as described herein. In some embodiments, the method 300 includes growing a crystal ingot along one of a <100>, <110>, and <111> crystal growth orientation using, for example, a seed crystal having the same crystal orientation as the desired crystal growth orientation.

Ingots grown according to the method 300 may be grown to any suitable diameter that enables the methods to be performed as described herein. In some embodiments, the method 300 includes growing a crystal ingot to a diameter of no less than about 150 mm, no less than about 200 mm, no less than about 300 mm, no less than about 400 mm, and even up to about 450 mm.

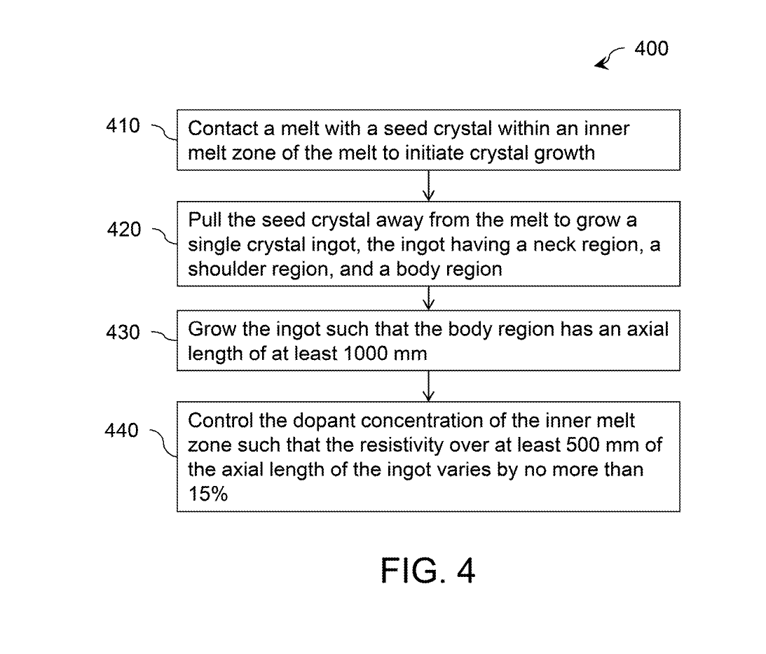

FIG. 4 is a flow chart of another example method 400 of growing a single crystal ingot from a melt of semiconductor or solar material using the above-described model. The melt includes an inner melt zone separated from an outer melt zone by one or more fluid barriers. The method 400 generally includes contacting 410 the melt with a seed crystal within the inner melt zone to initiate crystal growth, pulling 420 the seed crystal away from the melt to grow a single crystal ingot, the ingot having a neck region, a shoulder region, and a body region, growing 430 the ingot such that the body region has an axial length of at least (i.e., no less than) 1,000 mm, and controlling 440 a dopant concentration of the inner melt zone such that the resistivity over at least 500 mm of the axial length of the ingot varies by no more than 15%. Controlling 440 the dopant concentration of the inner melt zone further includes using a model to predict the dopant concentration of the melt in the inner melt zone based at least in part on diffusion of the dopant between the inner melt zone and the outer melt zone, evaporation of the dopant from the melt, segregation of the dopant from the ingot being grown, and convective mass transfer between the inner melt zone and the outer melt zone.

In some embodiments, controlling 440 the dopant concentration of the inner melt zone may include controlling the dopant concentration of the inner melt zone such that the resistivity over at least 500 mm of the axial length of the ingot varies by no more than 10%, more suitably by no more than 7%, even more suitably by no more than 5%, even more suitably by no more than 3%, even more suitably by no more than 2%, and even more suitably by no more than 1%. In some embodiments, the axial length of the ingot over which the resistivity of the ingot is within the above-described resistivity limits is greater than 500 mm, including no less than about 1,000 mm, no less than about 1,500 mm, no less than about 2,000 mm, no less than about 2,500 mm, no less than about 3,000 mm, no less than about 3,500 mm, no less than about 4,000 mm, and even up to about 4,500 mm.

In some embodiments, growing 430 the ingot includes growing the ingot such that the body region has an axial length of no less than about 1,500 mm, no less than about 2,000 mm, no less than about 2,500 mm, no less than about 3,000 mm, no less than about 3,500 mm, no less than about 4,000 mm, and even up to about 4,500 mm.

In some embodiments, the method 400 includes growing multiple ingots from the melt, where each ingot has a substantially uniform axial resistivity profile. In some embodiments, for example, the ingot grown by the method 400 is a first ingot, and the method 400 further includes removing the first ingot from the melt, growing a second ingot from the melt having a body region with an axial length of at least (i.e., no less than) 1,000 mm, and controlling the dopant concentration of the inner melt zone such that the resistivity over at least 500 mm of the axial length of the second ingot varies by no more than 15%, more suitably by no more than 10%, even more suitably by no more than 7%, even more suitably by no more than 5%, even more suitably by no more than 3%, even more suitably by no more than 2%, and even more suitably by no more than 1%. This may be repeated for multiple ingots, e.g. up to about 6, 10, 15, 20 or more ingots.

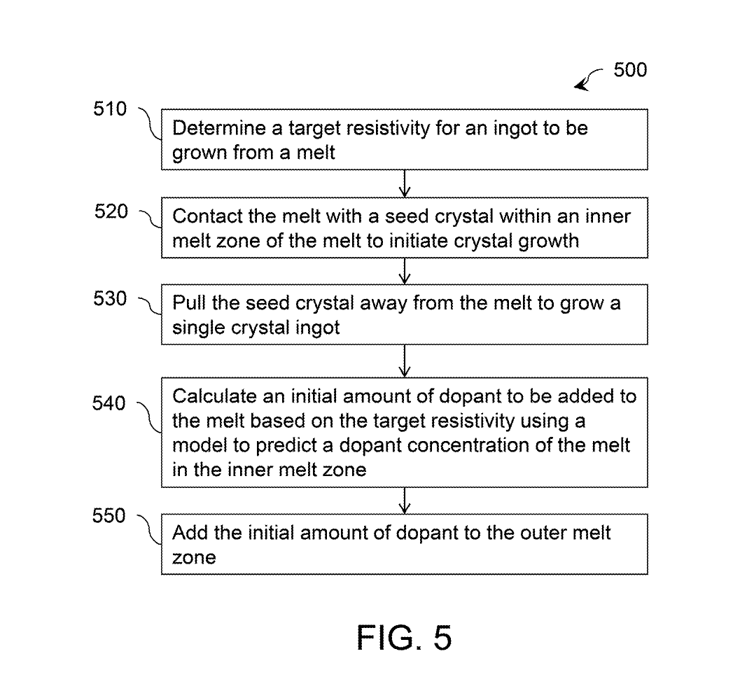

The methods and models described herein also facilitate reducing or eliminating the high resistivity transient region typically found at the seed end of semiconductor or solar grade ingots doped with highly volatile dopants. FIG. 5 is a flow chart of an example method 500 of growing a single crystal ingot from a melt of semiconductor or solar material using the above-described model to minimize the axial length of the high resistivity transient region. The melt includes an inner melt zone (e.g., inner melt zone 210, shown in FIG. 2) and an outer melt zone (e.g., outer melt zone 208 or transition melt zone 212, both shown in FIG. 2). The method 500 generally includes determining 510 a target resistivity for an ingot, contacting 520 the melt with a seed crystal within the inner melt zone to initiate crystal growth, pulling 530 the seed crystal away from the melt to grow a single crystal ingot, calculating 540 an initial amount of dopant to be added to the melt based on the target resistivity using a model to predict a dopant concentration of the melt in the inner melt zone, and adding 550 the initial amount of dopant to the outer melt zone. The model used to predict dopant concentration of the melt in the inner melt zone may be based at least in part on diffusion of the dopant between the inner melt zone and the outer melt zone, evaporation of the dopant from the melt, segregation of the dopant from the ingot being grown, and convective mass transfer between the inner melt zone and the outer melt zone.

The steps of determining 510 a target resistivity, contacting 520 the melt with a seed crystal, and pulling 530 the seed crystal away from the melt may be carried out in substantially the same manner as described above with reference to FIGS. 3 and 4. Further, the dopant added to the melt may include any of the dopants described above with reference to FIGS. 3 and 4.

In some embodiments, calculating 540 the initial amount of dopant and adding 550 the additional amount of dopant are carried out so as to minimize the axial length of the high resistivity transient region in the ingot. At the time the initial dopant is added to the melt, there are generally two competing process requirements. Specifically, the two competing process requirements are maintaining the dopant concentration in the inner melt zone at a level below the constitutional supercooling limit to enable successful crystal growth, and reaching the target resistivity as soon as possible to minimize the axial length of the high resistivity transient region in the ingot. Accordingly, in some embodiments, calculating 540 the initial amount of dopant is based on one or more of a constitutional supercooling limit associated with the dopant and an amount of dopant needed to reach the target resistivity within a certain amount of time so as to minimize the length of the high resistivity transient region.

Further, adding 550 the initial amount of dopant may include adding the initial amount to the melt only after crystal growth is initiated to avoid loss of structure during the necking and shoulder growth stages of ingot growth. In some embodiments, for example, a relatively large amount of initial dopant (e.g., as compared to the dopant feed rate used to maintain the dopant concentration of the melt during ingot growth) is added to the outer melt zone only after crystal growth is initiated, such as during formation of at least one of a neck region of the ingot, a shoulder region of the ingot, and a body region of the ingot. In some embodiments, adding 550 the initial amount of dopant includes adding the initial amount of dopant to a transition melt zone (e.g., transition melt zone 212, shown in FIG. 2) between the inner melt zone and an outermost melt zone of the melt. Further, in some embodiments, adding 550 the initial amount of dopant includes adding the initial amount of dopant in multiple doses, where each dose is added at a different time so as to avoid a spike in dopant concentration that may exceed the constitutional supercooling limit associated with the dopant. In other embodiments, adding 550 the initial amount of dopant includes adding the initial amount of dopant before necking, or before initiation of crystal growth.

The methods described herein also facilitate extending the run time of CCZ processes by controlling and reducing deposits of evaporated oxides and other volatile species on crystal growing parts that might otherwise require maintenance and/or cleaning of the crystal growing system in which the CCZ process is carried out. The methods described herein thereby enable the production of more ingots and/or longer ingots.

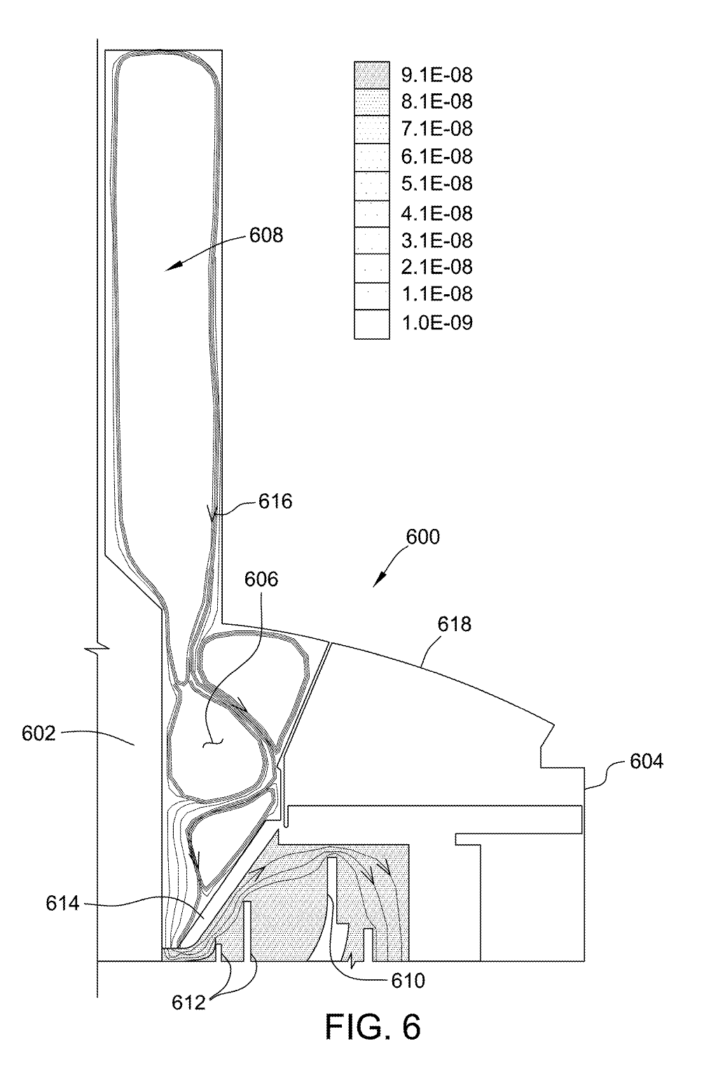

FIG. 6 is a partial cross-section of a crystal growing system 600 illustrating computer simulated flow streamlines of a carrier gas flowing through the crystal growing system 600 while a crystal ingot 602 is being grown. Also shown in FIG. 6 is a computer simulated contour plot of the mass fraction of gaseous SiO within the crystal growing system 600 during growth of the crystal ingot 602, wherein densely shaded areas indicate a relatively high mass fraction of gaseous SiO. The streamlines and contour plot were generated using a gas inlet flow rate of 30 standard liters per minute (slpm), and an operating pressure of 65 Torr.

The crystal growing system 600 includes a housing 604 defining a growth chamber 606 and a removal chamber 608 from which the crystal ingot 602 is removed once the crystal growth process is completed. The crystal growing system 600 also includes a crucible 610 containing a melt of semiconductor or solar grade material, two fluid barriers 612 separating the melt into three different melt zones, and a heat shield 614. The carrier gas is introduced into the crystal growing system 600 through a gas inlet 616 located along the removal chamber 608. The housing 604 includes an upper dome 618, which may include one or more view ports (not shown in FIG. 6) to enable an operator to monitor the growth process.

As shown in FIG. 6, at least some of the carrier gas introduced into the crystal growing system 600 eventually flows downward along the growing ingot 602, and between an opening defined between the ingot 602 and the heat shield 614. The gas then flows along the surface of the melt between the heat shield 614 and the melt, carrying with it gaseous SiO and particulates to one or more exhaust outlets (not shown). As shown in FIG. 6, several recirculation zones are created within the upper portion of the growth chamber 606 as a result of the flowing carrier gas. These recirculation zones are generally confined to the upper portion of the growth chamber 606 and remote from the melt while the ingot 602 is being grown. As a result, the amount of gaseous SiO carried away from the melt surface into the upper portion of the growth chamber 606 by the carrier gas is limited, as indicated by the SiO mass fraction contour plot.

The amount of SiO particulate deposition on components of crystal growing systems is directly related to the amount of gaseous SiO adjacent the components during the crystal growing process. Thus, according to the model used to generate the computer simulated streamlines and contour plot of FIG. 6, relatively little SiO particulate deposition will occur within upper portions of the growth chamber 606 while the ingot 602 is being grown.

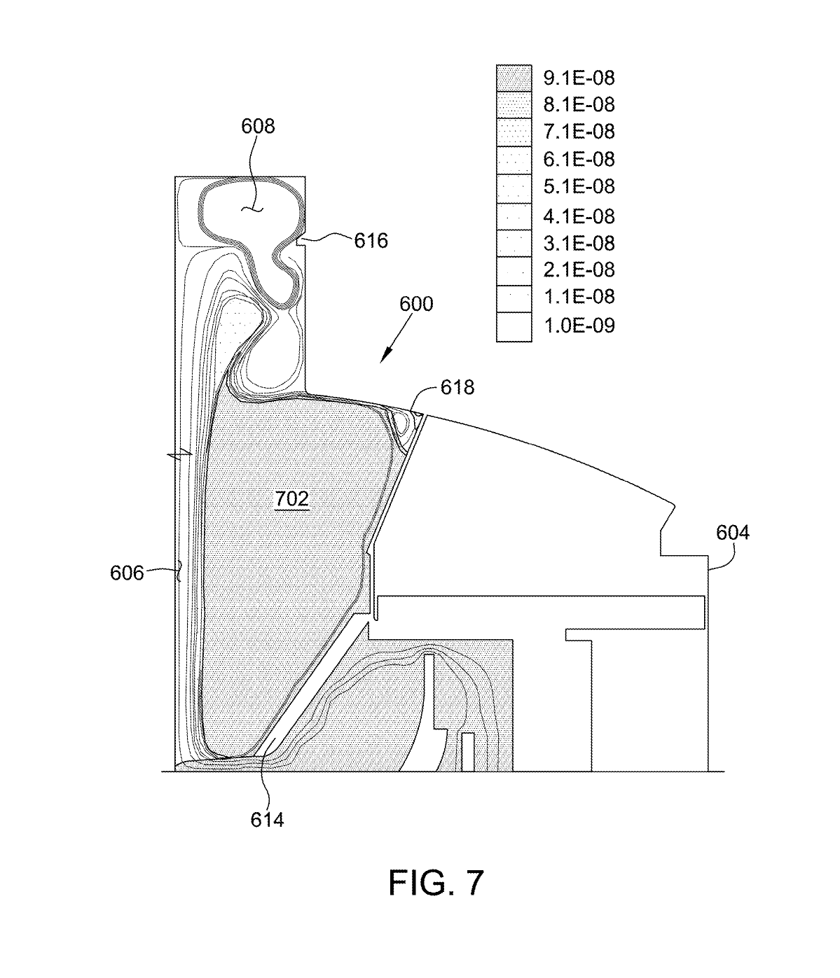

FIG. 7 illustrates the flow streamlines of carrier gas flowing through the crystal growing system 600 after the crystal ingot 602 (FIG. 6) is separated from the melt and removed from the growth chamber 606 of the crystal growing system 600. The streamlines and contour plot of FIG. 7 were generated using the same gas inlet flow rate and operating pressure as FIG. 6 (i.e., a gas inlet flow rate of 30 slpm, and an operating pressure of 65 Torr).

As shown in FIG. 7, when the ingot 602 (FIG. 6) is separated from the melt and removed from the growth chamber 606, a large recirculation zone 702 is created, extending from the melt surface to the dome 618 of the housing 604. Carrier gas within the recirculation zone carries particulates, such as SiO, located near the melt surface into the upper portion of the growth chamber 606, resulting in a relatively high mass fraction of gaseous SiO within the upper portion of the growth chamber 606, as indicated by the SiO mass fraction contour plot. Thus, at a constant gas inlet flow rate and operating pressure, the deposition of SiO particulates within upper portions of the growth chamber is enhanced once the ingot 602 (FIG. 6) is separated from the melt and removed from the growth chamber 606.

The deposition rate on the dome 618 of the crystal growing system 600 can be quantified using the equation:

$${R}_{D} = {\int }_{A}^{ } {D}_{SiO} ( \vec{∇} {C}_{SiO} ) \cdot \vec{n} dA \qquad Eq . 6$$

where R_{D} is the mass rate of deposition of SiO on an area A of the dome 618, D_{SiO} is the diffusivity of SiO in gas, C_{SiO} is the concentration of SiO in gas, and \vec{n} is the unit normal vector.

Equation 6 can be used to determine the effect of varying the operating pressure and gas inlet flow rate on the deposition rate of SiO on the dome 618 of the crystal growing system 600.

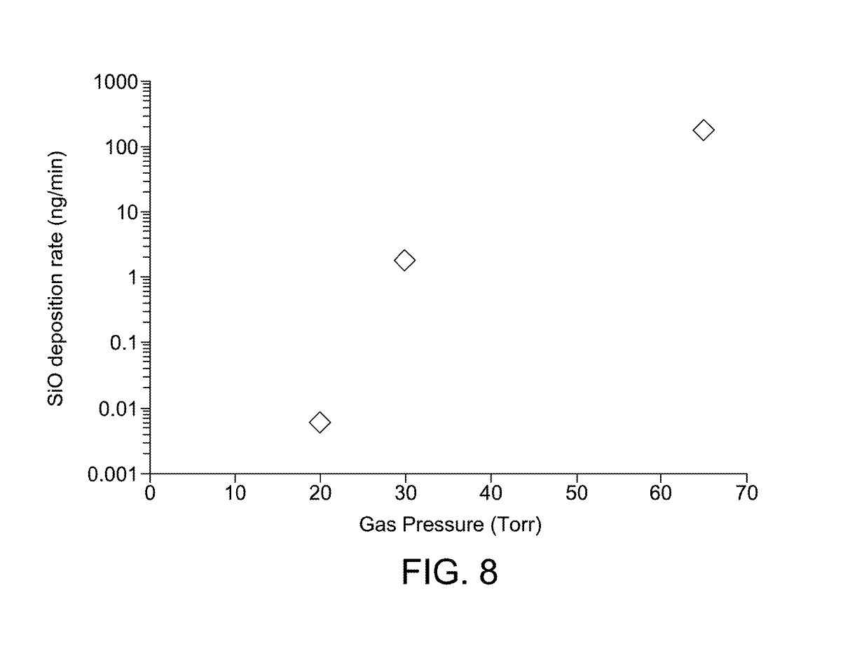

FIG. 8 is a graph illustrating the SiO deposition rate on the dome 616 of the crystal growing system 600 at a constant gas inlet flow rate and various operating pressures. As indicated by FIG. 8, decreasing the operating pressure within the crystal growing system 600 results in a decrease in the SiO deposition rate, despite an increase in the evaporation rate of SiO from the melt.

Without being bound by any particular theory, the reduction in SiO deposition rates at lower operating pressures is believed to be the result of a localized high gas flow rate near the surface of the melt, resulting in a “sweeping” effect that sweeps SiO particulates away from the hot zone and towards an exhaust of the crystal growing system. Additionally, it is believed that the localized high flow rate of carrier gas near the surface of the melt decouples recirculation zones from the surface of the melt, thereby inhibiting evaporated species, such as SiO, from being drawn into upper portions of the growth chamber.

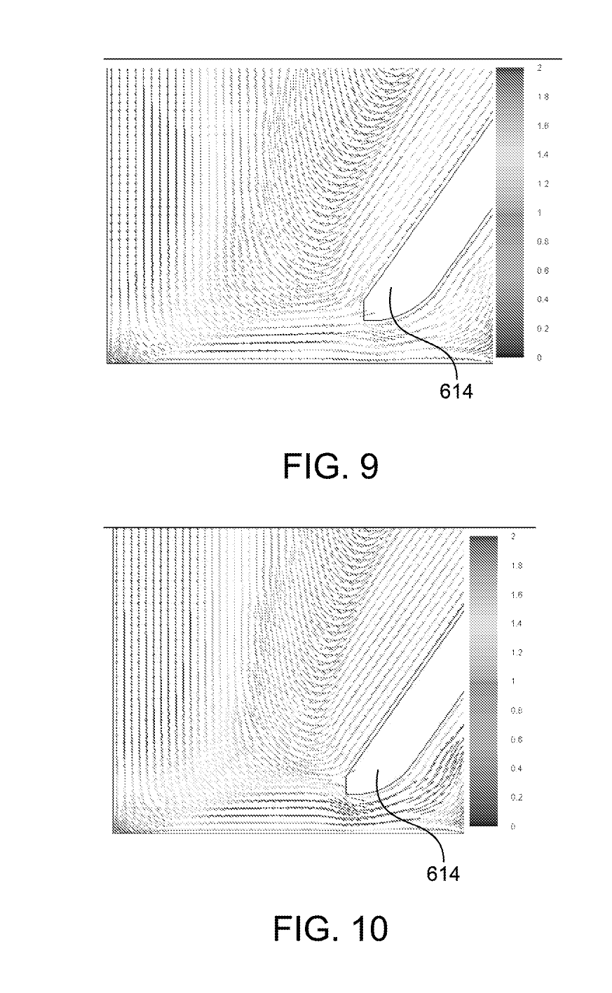

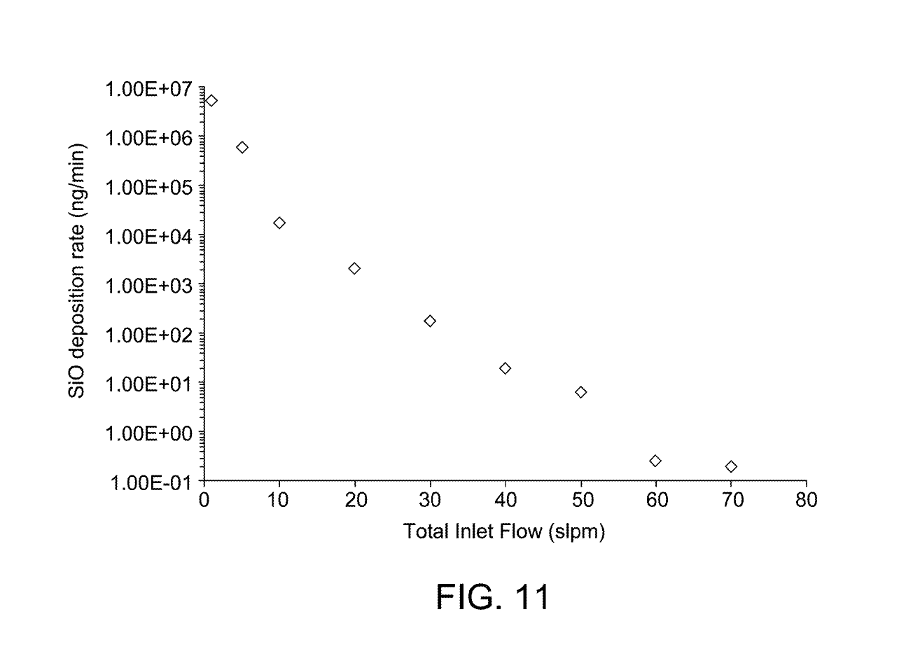

FIGS. 9 and 10 are enlarged partial views of the crystal growing system 600 of FIG. 6 illustrating velocity vector plots of the carrier gas near the surface of the melt at a constant gas inlet flow rate and two different operating pressures. Specifically, FIG. 9 shows a velocity vector plot for the carrier gas at an operating pressure of 65 Torr and a gas inlet flow rate of 30 slpm, and FIG. 10 shows a velocity vector plot for the carrier gas at an operating pressure of 30 Torr and 30 slpm. As indicated by FIGS. 9 and 10, the flow rate of the carrier gas between the melt surface and the heat shield 614 is greatly enhanced at the reduced operating pressure of 30 Torr. This increase in flow rate of the carrier gas near the melt surface at lower pressures is believed to decouple the recirculation zone 702 shown in FIG. 7 from the surface of the melt, thereby reducing the amount of gaseous SiO carried into the upper portion of the growth chamber 606.

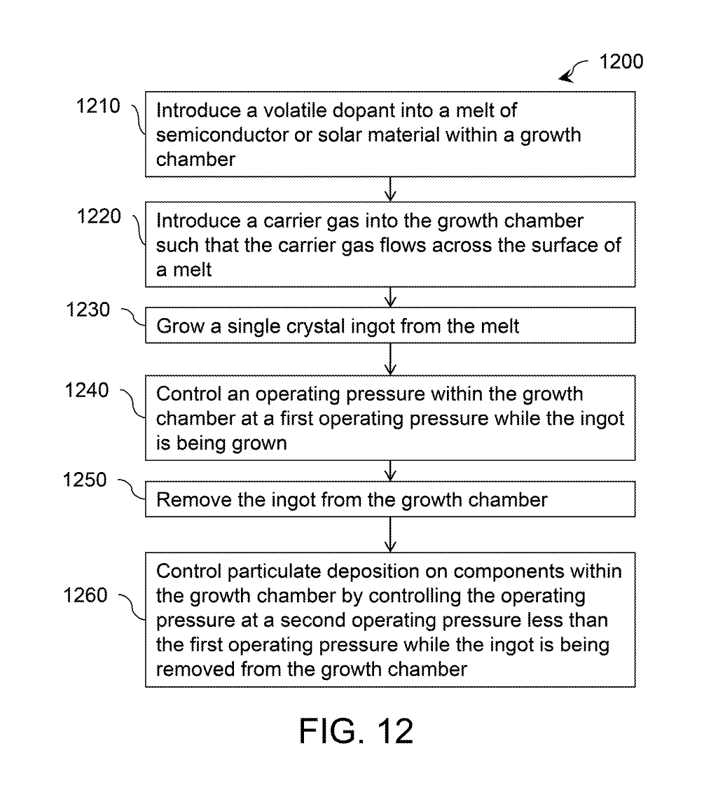

A similar effect may be achieved by increasing the gas inlet flow rate of the carrier gas. FIG. 11, for example, is a graph illustrating the SiO deposition rate on the dome 618 of the crystal growing system 600 at a constant operating pressure and various gas inlet flow rates based on Equation 6. As indicated by FIG. 11, increasing the total inlet flow rate of the carrier gas results in a decrease in the SiO deposition rate.

Accordingly, the SiO deposition rate within the upper portion of the growth chamber 606 can be decreased by decreasing the operating pressure of the crystal growing system 600 and/or increasing the inlet flow rate of the carrier gas once the ingot 602 is separated from the melt and/or removed from the growth chamber 606.

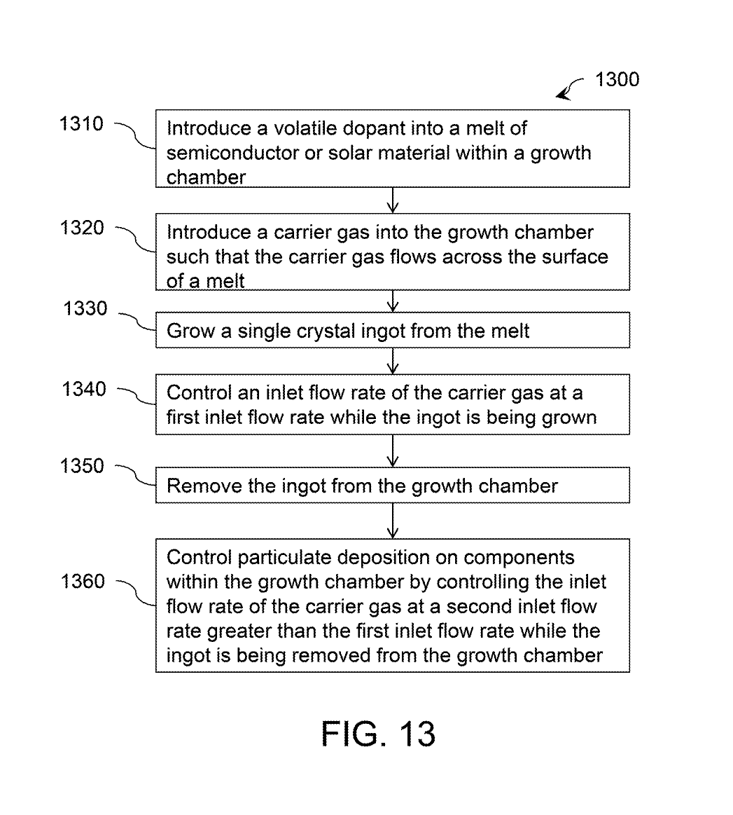

FIG. 12 is a flow chart of an example method 1200 of growing a single crystal ingot from a melt of semiconductor or solar material within a growth chamber using the above-described SiO deposition rate model. The method 1200 generally includes introducing 1210 a volatile dopant into the melt, introducing 1220 a carrier gas into the growth chamber such that the carrier gas flows across a surface of the melt, growing 1230 a single crystal ingot from the melt, controlling 1240 an operating pressure within the growth chamber at a first operating pressure while the ingot is being grown, removing 1250 the ingot from the growth chamber, and controlling 1260 particulate deposition on components within the growth chamber by controlling the operating pressure at a second operating pressure less than the first operating pressure while the ingot is being removed from the growth chamber. The carrier gas is introduced at an inlet flow rate, and has a localized flow rate across the surface of the melt. Controlling the operating pressure at the second operating pressure results in the localized flow rate of the carrier gas across the surface of the melt increasing.

Controlling 1260 particulate deposition on components within the growth chamber generally includes inhibiting particulate deposition on components within the growth chamber. As used herein, the term “particulates” includes oxide species evaporated from a melt of semiconductor or solar material including, for example and without limitation, SiOₓ species, such as SiO and SiO₂, and dopant oxide species, such as DOₓ, where D represents a dopant (e.g., arsenic, antimony, red phosphorous, indium, and gallium) and x is a number greater than zero.

In some embodiments, controlling 1260 particulate deposition on components within the growth chamber includes reducing the operating pressure within the growth chamber while the ingot is still being grown. In other embodiments, controlling 1260 particulate deposition on components within the growth chamber includes reducing the operating pressure within the growth chamber after the ingot is separated from the melt.

In some embodiments, controlling 1260 particulate deposition on components within the growth chamber includes maintaining the inlet flow rate of the carrier gas at the same inlet flow rate during ingot growth and during removal of the ingot from the growth chamber. That is, the inlet flow rate of the carrier gas is substantially the same at the first operating pressure and the second operating pressure. In other embodiments, the inlet flow rate of the carrier gas is controlled at a first inlet flow rate while the crystal is being grown, and increased to a second inlet flow rate greater than the first inlet flow rate while the ingot is being removed from the growth chamber. The inlet flow rate may be increased to the second inlet flow rate while the ingot is being grown, or after the ingot is separated from the melt.

In some embodiments, introducing 1210 a volatile dopant into the melt includes introducing a dopant selected from the group consisting of arsenic, antimony, red phosphorous, indium, and gallium.

In some embodiments, the ingot grown from the melt is a first ingot, and the method 1200 further includes growing a second ingot from the melt after the first ingot is removed from the growth chamber. In such embodiments, the operating pressure within the growth chamber may be maintained at a pressure below the first operating pressure at least until growth of the second ingot begins in order to control particulate deposition of components within the growth chamber.

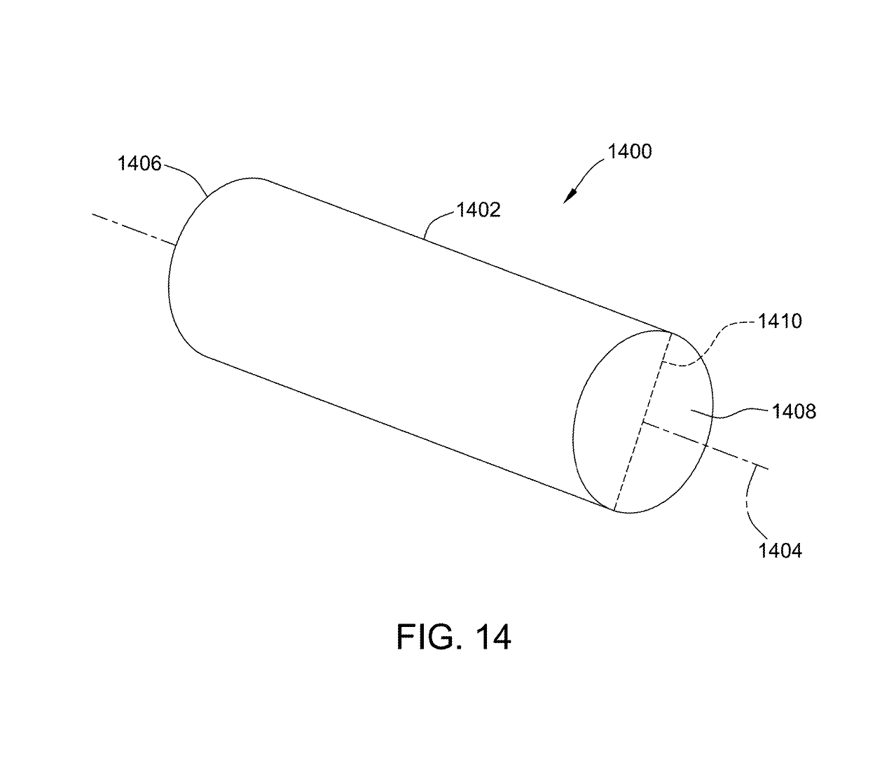

FIG. 13 is a flow chart of another example method 1300 of growing a single crystal ingot from a melt of semiconductor or solar material within a growth chamber using the above-described SiO deposition rate model. The method 1300 generally includes introducing 1310 a volatile dopant into the melt, introducing 1320 a carrier gas into the growth chamber such that the carrier gas flows across a surface of the melt, the carrier gas having an inlet flow rate and a localized flow rate across the surface of the melt, growing 1330 a single crystal ingot from the melt, controlling 1340 the inlet flow rate of the carrier gas at a first inlet flow rate while the ingot is being grown, removing 1350 the ingot from the growth chamber, and controlling 1360 particulate deposition on components within the growth chamber by controlling the inlet flow rate of the carrier gas at a second inlet flow rate greater than the first inlet flow rate while the ingot is being removed from the growth chamber. Controlling the inlet flow rate at the second inlet flow rate causes the localized flow rate of the carrier gas across the surface of the melt to increase.

In some embodiments, controlling 1360 particulate deposition on components within the growth chamber includes increasing the inlet flow rate to the second inlet flow rate while the ingot is being grown. In other embodiments, controlling 1360 particulate deposition on components within the growth chamber includes increasing the inlet flow rate to the second inlet flow rate after the ingot is separated from the melt.

In some embodiments, the method 1300 includes controlling an operating pressure within the growth chamber. In some embodiments, the operating pressure within the growth chamber is controlled at a first operating pressure while the ingot is being grown and a second operating pressure while the ingot is being removed from the growth chamber. In some embodiments, the first operating pressure is substantially equal to the second operating pressure. In other embodiments, the second operating pressure is less than the first operating pressure.

The methods described herein facilitate the production of multiple, single crystal semiconductor or solar grade ingots that are doped with one or more volatile dopants. In some aspects, for example, the methods described herein facilitate controlling the axial resistivity profile of ingots grown by the CCZ method using a model to predict dopant concentration of the growth zone of a melt at any point during the CCZ process. In particular, the methods described herein control the addition of dopants to a melt using a model that predicts dopant concentration in the melt based on, among other things, dopant evaporation, convective mass transport between adjacent melt zones, diffusion between adjacent melt zones resulting from dopant concentration gradients, and dopant segregation from the ingot being grown. By accounting for numerous dopant transport mechanisms, the methods described herein enable the production of single crystal ingots having substantially uniform axial resistivity profile.

Further, in some aspects, the methods described herein facilitate reducing or eliminating the high resistivity transient region typically found in semiconductor or solar grade crystals doped with highly volatile dopants. In particular, the methods described herein use the above-described model to calculate an initial amount of dopant to be added to a melt to reach a target resistivity as quickly as possible while maintaining the dopant concentration in the melt at a level below a constitutional supercooling limit to enable successful crystal growth.

In yet other aspects, the methods described herein facilitate controlling particulate deposition on components within the growth chamber of a crystal growing system during a CCZ growth process. In particular, the methods described herein control at least one of an operating pressure within the growth chamber of a crystal growing system and an inlet flow rate of a carrier gas to create a localized high flow rate of carrier gas near the surface of a melt. Without being bound by any particular theory, it is believed that the localized high flow rate of carrier gas near the surface of the melt decouples recirculation zones from the surface of the melt, thereby inhibiting evaporated species, such as SiOₓ and DOₓ, from being drawn into upper portions of the growth chamber. By reducing particulate deposition during CCZ growth processes, the methods described herein facilitate increasing the run time of such processes and decreasing the down time of crystal growing systems, thereby increasing the productivity of such systems.

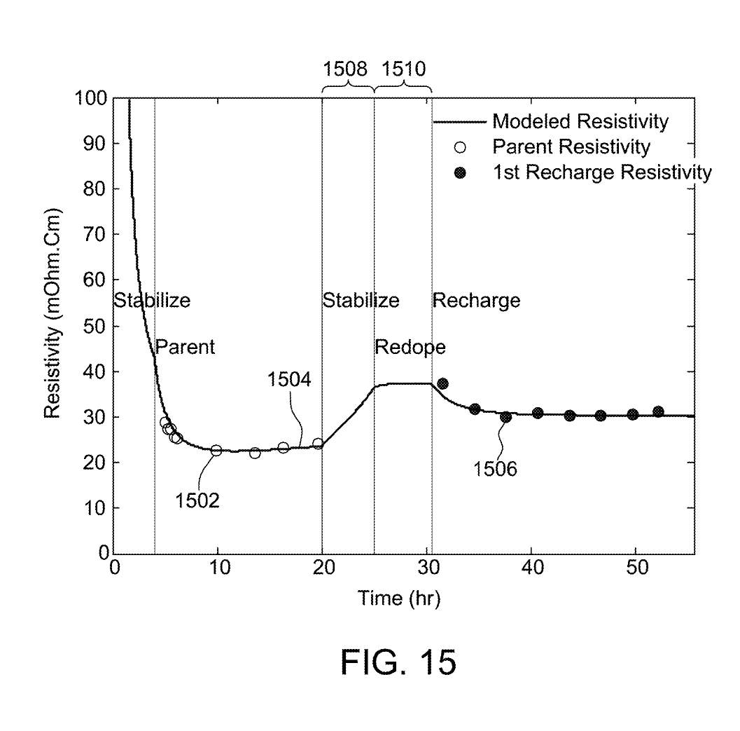

As noted above, the methods described herein enable the production of multiple, single crystal semiconductor or solar grade ingots that are doped with one or more volatile dopants and have a highly uniform axial resistivity profile. FIG. 14 is a perspective view of a single crystal silicon ingot 1400 grown by a CCZ method using the methods described herein. The ingot 1400 has a constant diameter region 1402, and a central axis 1404 extending from a seed end 1406 of the constant diameter region 1402 to a terminal end 1408 of the constant diameter region 1402. The ingot 1400 has an axial length as measured from the seed end 1406 to the terminal end 1408, and a diameter 1410 measured along a plane perpendicular to the central axis 1404.

In some embodiments, the axial length of the ingot 1400 may be no less than about 1,000 mm long, no less than about 1,500 mm long, no less than about 2,000 mm long, no less than about 3,000 mm long, no less than about 3,500 mm long, no less than about 4,000 mm long, and even up to about 4,500 mm long. Further, in some embodiments, the constant diameter region 1402 of the ingot 1400 has diameter 1410 of no less than about 150 mm, no less than about 200 mm, no less than about 300 mm, no less than about 400 mm, and even up to about 450 mm.

The ingot 1400 is doped with an electrically active dopant to modify the resistivity of the ingot. As used herein, the term “electrically active dopant” generally refers to a foreign substance that, when added to a base semiconductor or solar grade material, alters the electrical properties of the semiconductor or solar grade material by modifying the electron and/or hole carrier concentration of the semiconductor or solar grade material. Electrically active dopants include, for example and without limitation, boron, phosphorous, indium, antimony, aluminum arsenic, gallium, red phosphorous, and germanium. In some embodiments, the ingot 1400 is doped with a dopant selected from the group consisting of arsenic, antimony, red phosphorous, and indium. In other embodiments, the ingot 1400 is doped with a dopant selected from the group consisting of boron, phosphorous, indium, antimony, aluminum arsenic, gallium, red phosphorous, germanium, and combinations thereof.

The ingot 1400 has a highly uniform axial resistivity profile. In some embodiments, for example, the resistivity over at least 500 mm of the axial length varies by no more than 15%, more suitably, by no more than 10%, even more suitably, by no more than 5%, even more suitably, by no more than 3%, yet even more suitably, by no more than 2%, and yet even more suitably, by no more than 1%. Further, in some embodiments, the resistivity over at least 1,000 mm of the axial length varies by no more than 15%, more suitably, by no more than 10%, even more suitably, by no more than 5%, even more suitably, by no more than 3%, yet even more suitably, by no more than 2%, and yet even more suitably, by no more than 1%. In a particular embodiment, the ingot 1400 is doped with indium, and the resistivity over at least 2,000 mm of the axial length varies by no more than 7%.

In some embodiments, the ingot 1400 has a mean resistivity of no more than 30 mΩ-cm, no more than 20 mΩ-cm, no more than 10 mΩ-cm, no more than 3 mΩ-cm, and even no more than 2 mΩ-cm. In one particular embodiment, the ingot 1400 is doped with arsenic, and has a mean resistivity of no more than about 3 mΩ-cm, no more than about 2 mΩ-cm, or even no more than about 1.5 mΩ-cm. In another particular embodiment, the ingot 1400 is doped with antimony, and has a mean resistivity of no more than about 30 mΩ-cm, no more than about 20 mΩ-cm, or even no more than about 10 mΩ-cm. In another particular embodiment, the ingot 1400 is doped with red phosphorus, and has a mean resistivity of no more than about 1.7 mΩ-cm, no more than about 1.2 mΩ-cm, or even no more than about 1 mΩ-cm.

In some embodiments, the ingot 1400 has a crystal growth orientation along the <100> direction, the <110> direction, or the <111> direction.

### EXAMPLES

The following examples are non-limiting.

### Example 1. Antimony-Doped Monocrystalline Silicon Ingot

An antimony-doped monocrystalline silicon ingot was grown in a three melt zone crystal growing system having a configuration similar to the crystal growing system 100 shown in FIG. 1. A silicon melt was prepared in a crucible, and an initial amount of 150 grams of antimony was added to the outer melt zone of the melt during a stabilization period. The melt was allowed to stabilize for four hours after the initial amount of antimony was added, and a seed crystal was subsequently lowered into contact with the melt to initiate crystal growth.

The body of the ingot was grown to a length of about 1,200 mm, and a diameter of about 200 mm. During growth of the ingot body, no dopant was added to the melt.

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug.

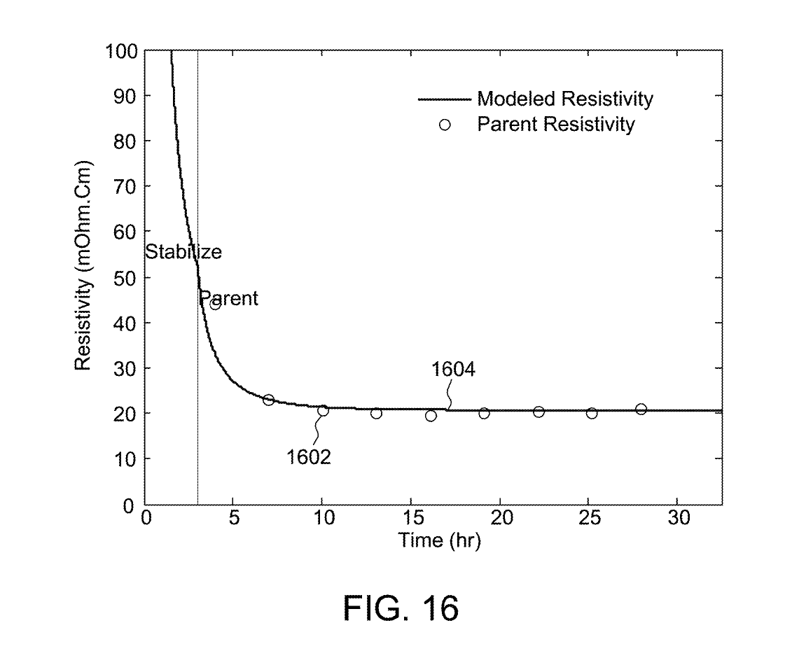

The measured resistivity values are shown in FIG. 15, and are plotted as a function of time during the Czochralski growth process, using the time at which the initial amount of dopant was added as the starting time. Specifically, the measured resistivity values from the ingot in Example 1 are indicated by points 1502 in FIG. 15. The first line labeled “Stabilize” in FIG. 15 indicates the beginning of a melt stabilization period for an initial or parent crystal to be grown from the melt, the line labeled “Parent” in FIG. 15 indicates the start of parent crystal growth, the second line labeled “Stabilize” indicates the end of parent crystal growth and the beginning of a melt stabilization period for a second or “recharge” crystal to be grown from the melt, the line labeled “Redope” indicates the time of initial doping for the second crystal, and the line labeled “Recharge” indicates the start of crystal growth for the second crystal.

The coefficients from Equations 2-4 were empirically determined using the measured resistivity values from the ingot of Example 1. Specifically, the measured resistivity values were related to the dopant concentration of the ingot using resistivity conversion tables standard in the art, such as standard SEMI MF723-0307 and SEMI F723-99, published by SEMI International Standards. The dopant concentration of the melt was then determined for each point in time corresponding to the axial position of the ingot from which each slug was selected using Equation 5 above. The coefficients from Equations 2-4 were then determined by solving the set of differential equations. The theoretical resistivity values predicted by the above model using the determined coefficients are plotted along line 1504 in FIG. 15.

### Example 2. Recharge Antimony-Doped Monocrystalline Silicon Ingot

A second antimony-doped monocrystalline silicon ingot was grown from the melt remaining in the crucible following growth of the antimony-doped ingot from Example 1. Following removal of the first ingot from the melt, the melt was permitted to stabilize for 10.5 hours. Five hours into the stabilization period, 25 grams of antimony were added to the melt. The melt was then permitted to stabilize for an additional 5.5 hours. Following the stabilization period, a seed crystal was lowered into contact with the melt to initiate crystal growth.

The body of the ingot was grown to a length of about 1,700 mm, and a diameter of about 200 mm. During growth of the ingot body, 0.209 grams of antimony were added to the melt for every 1 kilogram of silicon added to the melt.

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug. The measured resistivity values are indicated in FIG. 15 by points 1506. The stabilization and redoping periods are indicated by regions 1508 and 1510, respectively, in FIG. 15.

To account for the lower operating pressure and the resulting higher evaporation rate during the stabilization and redoping periods, a separate set of coefficients for Equations 2-4 were empirically determined using the measured resistivity values from Examples 1 and 2. The theoretical resistivity values predicted by the above model using the two sets of determined coefficients are plotted along line 1504 in FIG. 15.

### Example 3. Antimony-Doped Monocrystalline Silicon Ingot

Using the model with the empirically determined coefficients from Examples 1 and 2, a third antimony-doped monocrystalline silicon ingot was grown in a three melt zone crystal growing system having a configuration similar to the crystal growing system 100 shown in FIG. 1. The initial amount of antimony added to the melt and the feed rate of antimony were selected using the above-described model and empirically determined coefficients in order to achieve a highly uniform axial resistivity along the axial length of the ingot.

A silicon melt was prepared in a crucible, and an initial amount of 150 grams of antimony was added to the outer melt zone of the melt during a stabilization period. The melt was allowed to stabilize for three hours after the initial amount of antimony was added, and a seed crystal was subsequently lowered into contact with the melt to initiate crystal growth. The body of the ingot was grown to a length of about 2,000 mm, and a diameter of about 200 mm. During growth of the ingot body, antimony was added to the melt at a rate of 0.46 grams of antimony for every 1 kilogram of silicon added to the melt.

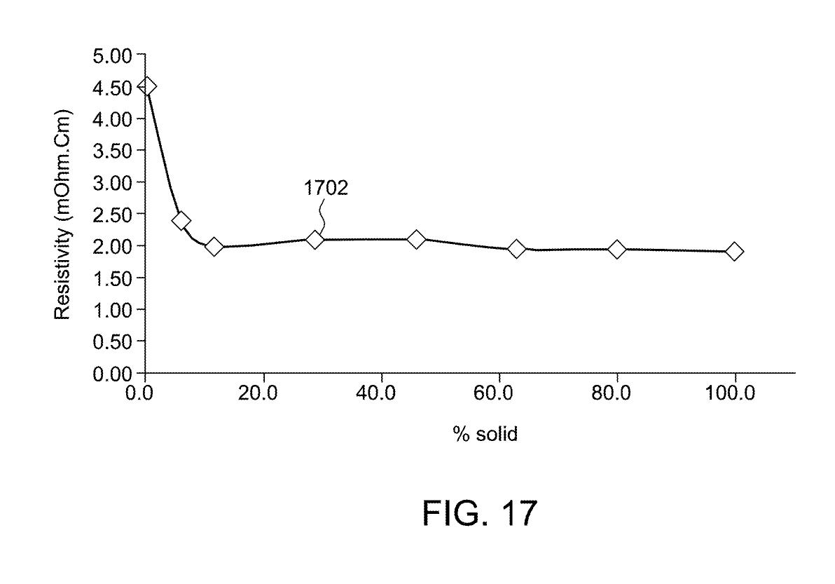

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug. The measured resistivity values are indicated in FIG. 16, and are plotted as a function of time during the Czochralski growth process, using the time at which the initial amount of dopant was added as the starting time. Specifically, the measured resistivity values from the ingot in Example 3 are indicated by points 1602 in FIG. 16. The theoretical resistivity values predicted by the above-described model are plotted along line 1604 in FIG. 16.

As shown in FIG. 16, the ingot from Example 3 has a highly uniform axial resistivity profile. More specifically, excluding resistivity values obtained from the high resistivity transient region, the ingot had an average resistivity of 20.6±1.0 mΩ-cm. In other words, the resistivity of the ingot varies by no more than 4.8% over 1,800 mm of the axial length of the ingot.

### Example 4. Arsenic-Doped Monocrystalline Silicon Ingot

An arsenic-doped monocrystalline silicon ingot was grown in a three melt zone crystal growing system having a configuration similar to the crystal growing system 100 shown in FIG. 1 using the above-described model to control the axial resistivity profile of the ingot. Specifically, coefficients for Equations 2-4 were empirically determined for arsenic in substantially the same manner as used in Examples 1 and 2, described above. An initial amount of arsenic and an arsenic feed rate for use during growth of the ingot body were determined using the model with the empirically determined coefficients based on a target resistivity for the ingot of 2 mΩ-cm.

A silicon melt was prepared in a crucible, and a first crystal was grown with a target resistivity of 2 mΩ-cm. The amount and timing of arsenic dopant addition were determined using the above-described model to achieve the target resistivity of 2 mΩ-cm. The first ingot was removed from the melt, and crystal growth of a second ingot was initiated by lowering a seed crystal into contact with the melt following a melt stabilization period. During growth of the neck region of the second ingot, and about 2.5 hours prior to initiating growth of the body region of the second ingot, 320 grams of arsenic dopant were added to the outer melt zone. About 1.5 hours after the initial arsenic doping for the second ingot, and during the crown phase of the second ingot, an additional 240 grams of arsenic dopant were added to the outer melt zone. The body of the second ingot was grown to a length of about 2000 mm, and a diameter of about 205 mm. During growth of the ingot body, arsenic was added to the melt at a rate of 7 grams of arsenic for every 1 kilogram of silicon added to the melt.

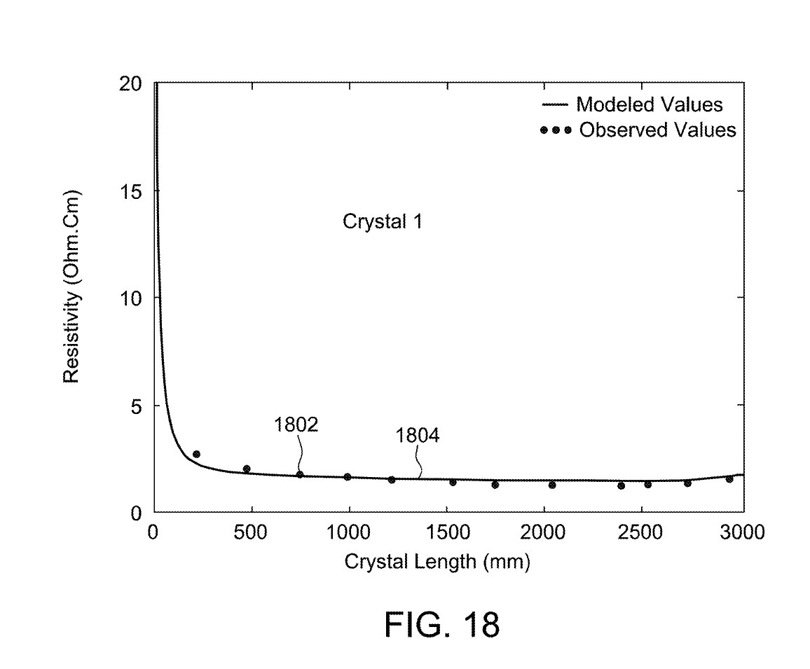

The second ingot was subsequently removed from the crystal growing system, and slugs having thicknesses of between about 1.1 mm and about 1.4 mm were cut from the second ingot. Slugs were selected for analysis from various lengths from the seed end of the ingot body. Each slug was tested for resistivity at the center of the slug. The measured resistivity values for slugs cut from the second ingot are indicated by points 1702 in FIG. 17.

As shown in FIG. 17, the second ingot from Example 4 has a highly uniform axial resistivity profile. More specifically, excluding resistivity values obtained from the high resistivity transient region, the second ingot had an average resistivity of 1.99±0.08 mΩ-cm. In other words, the resistivity of the ingot varies by no more than 4.0% over 1,800 mm of the axial length of the ingot.

### Example 5. Indium-Doped Monocrystalline Silicon Ingot

An indium-doped monocrystalline silicon ingot was grown in a three melt zone crystal growing system having a configuration similar to the crystal growing system 100 shown in FIG. 1 using the above-described model to control the axial resistivity profile of the ingot. Specifically, coefficients for Equations 2-4 were empirically determined for indium in substantially the same manner as used in Examples 1 and 2, described above. An initial amount of indium and an indium feed rate for use during growth of the ingot body were determined using the model with the empirically determined coefficients.

A silicon melt was prepared in a crucible, and crystal growth was initiated by lowering a seed crystal into contact with the melt. An initial amount of 90 grams of indium was added to the outer melt zone of the melt once formation of the ingot shoulder began. The body of the ingot was grown to a length of about 3,000 mm, and a diameter of about 200 mm. During growth of the ingot body, indium was added to the melt at a rate of 13 grams per hour.

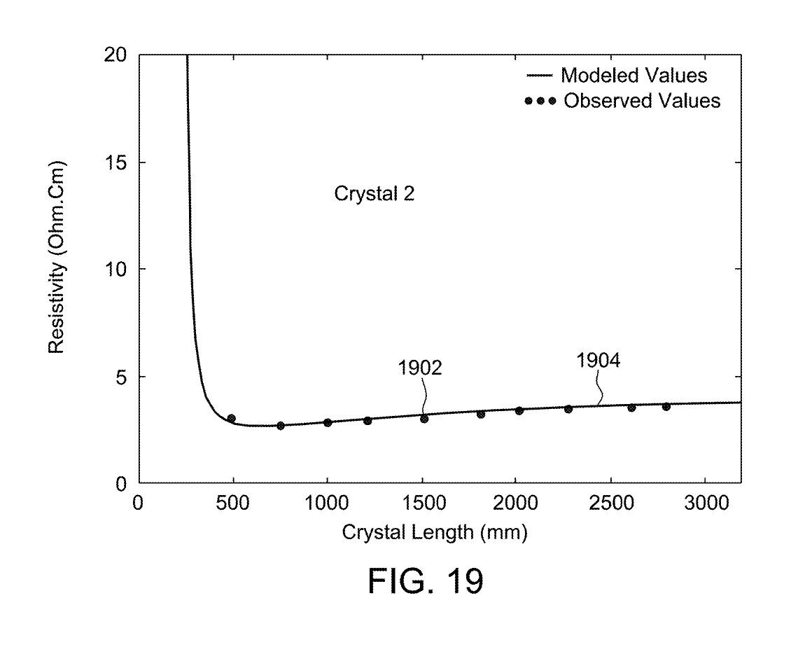

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug. The measured resistivity values are plotted in FIG. 18 at points 1802. The theoretical resistivity values predicted using the model described herein are plotted along line 1804 in FIG. 18.

Excluding resistivity values obtained from the high resistivity transient region, the ingot had an average resistivity of 1.57±0.42 Ω-cm, or an axial resistivity variance of about 26.8% over 2,500 mm of the axial length of the ingot.

### Example 6. Indium-Doped Monocrystalline Silicon Ingot

An indium-doped monocrystalline silicon ingot was grown in a three melt zone crystal growing system having a configuration similar to the crystal growing system 100 shown in FIG. 1 using the above-described model to control the axial resistivity profile of the ingot. Coefficients for Equations 2-4 were empirically determined for indium in substantially the same manner as used in Examples 1 and 2, described above. An initial amount of indium and an indium feed rate for use during growth of the ingot body were determined using the model with the empirically determined coefficients.

A silicon melt was prepared in a crucible, and crystal growth was initiated by lowering a seed crystal into contact with the melt. An initial amount of 70 grams of indium was added to the outer melt zone of the melt once the ingot body reached a length of 200 mm. The body of the ingot was grown to a length of about 3,000 mm, and a diameter of about 200 mm. During growth of the ingot body, indium was added to the melt at a rate of 3 grams per hour.

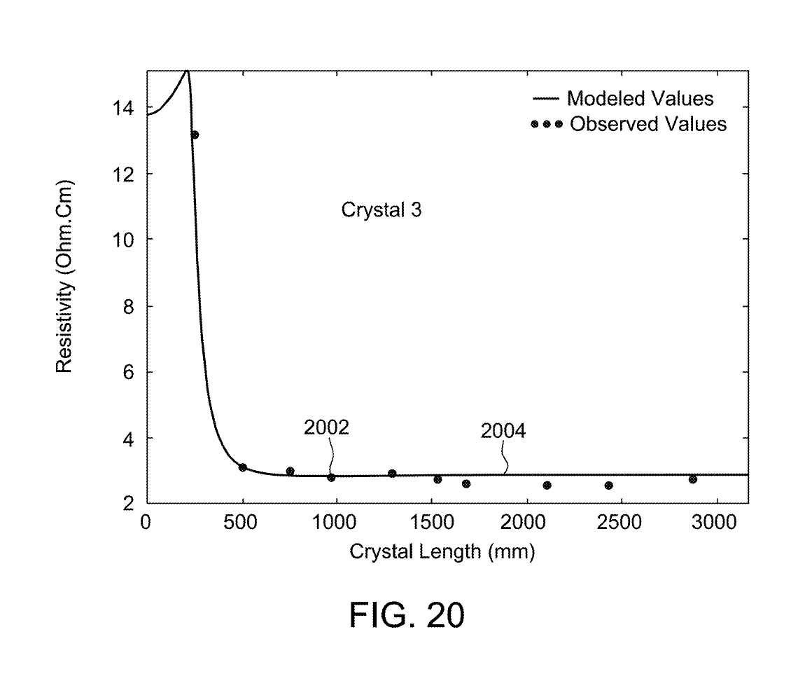

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug. The measured resistivity values are plotted in FIG. 19 at points 1902. The theoretical resistivity values predicted using the model described herein are plotted along line 1904 in FIG. 19.

Excluding resistivity values obtained from the high resistivity transient region, the ingot had an average resistivity of 3.22±0.31 Ω-cm, or an axial resistivity variance of about 9.6% over 2,500 mm of the axial length of the ingot.

### Example 7. Indium-Doped Monocrystalline Silicon Ingot

An indium-doped monocrystalline silicon ingot was grown in a three melt zone crystal growing system having a configuration similar to the crystal growing system 100 shown in FIG. 1 using the above-described model to control the axial resistivity profile of the ingot. Coefficients for Equations 2-4 were empirically determined for indium in substantially the same manner as used in Examples 1 and 2, described above. An initial amount of indium and an indium feed rate for use during growth of the ingot body were determined using the model with the empirically determined coefficients.

A silicon melt was prepared in a crucible, and crystal growth was initiated by lowering a seed crystal into contact with the melt. An initial amount of 50 grams of indium was added to the outer melt zone of the melt once the ingot body reached a length of 200 mm. The body of the ingot was grown to a length of about 3,000 mm, and a diameter of about 200 mm. During growth of the ingot body, indium was added to the melt at a rate of 4.5 grams per hour.

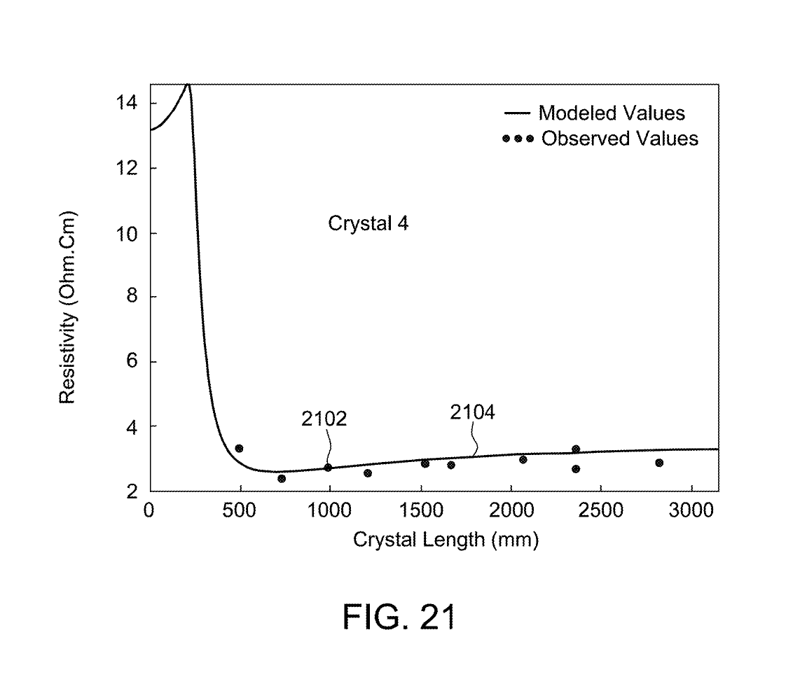

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug. The measured resistivity values are plotted in FIG. 20 at points 2002. The theoretical resistivity values predicted using the model described herein are plotted along line 2004 in FIG. 20.

Excluding resistivity values obtained from the high resistivity transient region, the ingot had an average resistivity of 2.76±0.19 Ω-cm, or an axial resistivity variance of about 6.9% over 2,500 mm of the axial length of the ingot.

### Example 8. Indium-Doped Monocrystalline Silicon Ingot

An indium-doped monocrystalline silicon ingot was grown in a three melt zone crystal growing system having a configuration similar to the crystal growing system 100 shown in FIG. 1 using the above-described model to control the axial resistivity profile of the ingot. Coefficients for Equations 2-4 were empirically determined for indium in substantially the same manner as used in Examples 1 and 2, described above. An initial amount of indium and an indium feed rate for use during growth of the ingot body were determined using the model with the empirically determined coefficients.

A silicon melt was prepared in a crucible, and crystal growth was initiated by lowering a seed crystal into contact with the melt. An initial amount of 70 grams of indium was added to the outer melt zone of the melt once the ingot body reached a length of 200 mm. The body of the ingot was grown to a length of about 3,000 mm, and a diameter of about 200 mm. During growth of the ingot body, indium was added to the melt at a rate of 5 grams per hour.

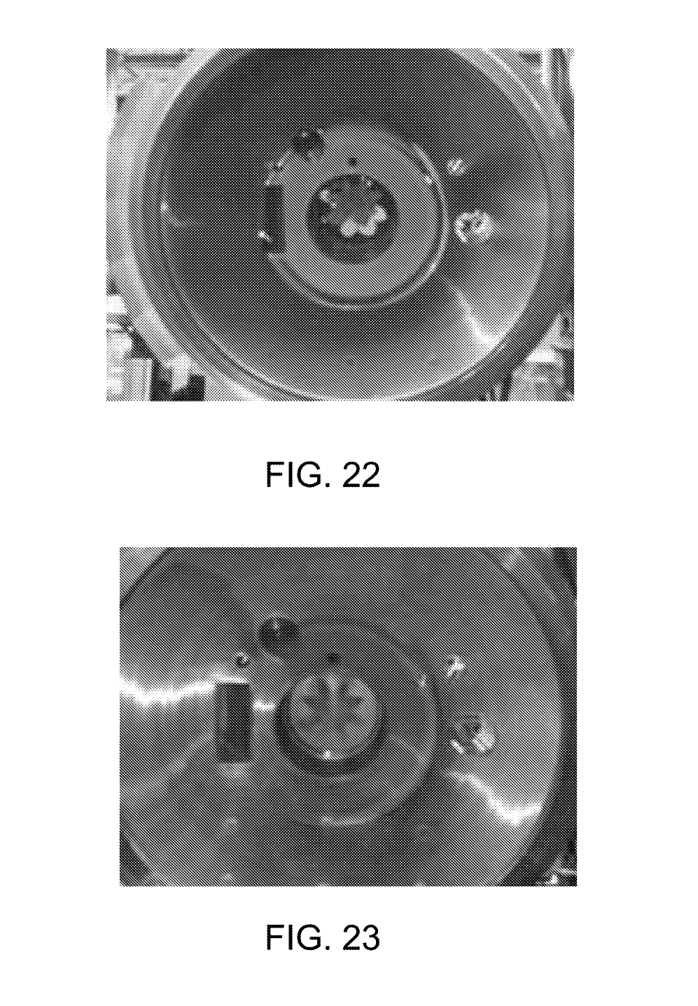

The ingot was subsequently removed from the crystal growing system, and slugs having thicknesses of between about 1.1 mm and about 1.4 mm were cut from the ingot. Slugs were selected for analysis from various lengths from the seed end of the ingot body. Each slug was tested for resistivity at the center of the slug. The measured resistivity values are plotted in FIG. 21 at points 2102. The theoretical resistivity values predicted using the model described herein are plotted along line 2104 in FIG. 21.

Excluding resistivity values obtained from the high resistivity transient region, the ingot had an average resistivity of 2.42±0.15 Ω-cm, or an axial resistivity variance of about 6.2% over 2,500 mm of the axial length of the ingot.

### Examples 9-11. Particulate Deposition on Upper Dome of Crystal Growing System

Three separate Czochralski growth processes were carried out based on the above-described methods for controlling particulate deposition. The operating parameters and conditions for each growth process were substantially identical, except the operating pressure and the inlet flow rate of carrier gas varied in each growth process once the crystal ingot was removed from the growth chamber. Specifically, for each growth process, a crystal ingot having a diameter of about 200 mm was grown under an operating pressure of 65 Torr and an inlet flow rate of carrier gas of 120 slpm.

In the first growth process, the operating pressure was maintained at 65 Torr and the inlet flow rate of carrier gas was decreased to 100 slpm after the ingot was removed from the growth chamber. In the second growth process, the operating pressure was decreased to 30 Torr and the inlet flow rate of carrier gas was increased to 140 slpm after the ingot was removed from the growth chamber. In the third growth process, the operating pressure was decreased to 20 Torr and the inlet flow rate of carrier gas was increased to 140 slpm after the ingot was removed from the growth chamber.

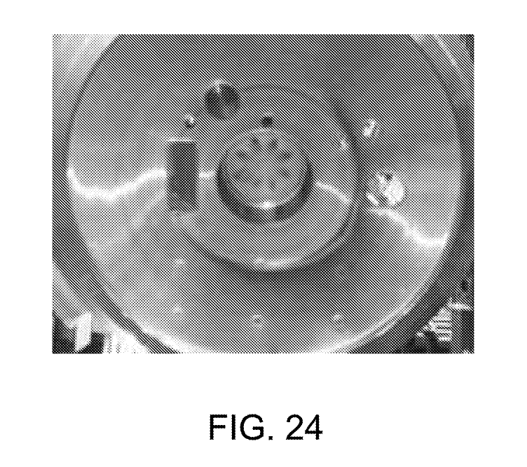

Following completion of each growth process, the upper dome of the crystal growing system in which the growth process was carried out was visually inspected to qualitatively analyze the amount of particulate deposition. FIGS. 22-24 are photographs of the upper dome of the crystal growing system in which the first, second, and third growth processes were carried out, respectively. As shown in FIGS. 22-24, the upper dome used for the third growth process is more reflective than the upper domes used for the first and second growth processes, indicating a lower rate of particulate deposition. Conversely, the upper dome used for the first growth process is significantly duller than the upper domes used for the second and third growth processes, indicating a higher rate of particulate deposition. Thus, Examples 9-11 indicate that particulate deposition can be controlled during a Czochralski growth process by adjusting the operating pressure within the growth chamber and/or the inlet flow rate of the carrier gas.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

1. A method of growing a single crystal ingot from a melt of semiconductor or solar material including an inner melt zone separated from an outer melt zone by one or more fluid barriers, the method comprising:
contacting the melt with a seed crystal within the inner melt zone to initiate crystal growth;
pulling the seed crystal away from the melt to grow a single crystal ingot, the ingot having a neck region, a shoulder region, and a body region;
growing the ingot such that the body region has an axial length; and
controlling a dopant concentration of the inner melt zone such that the resistivity over at least 500 mm of the axial length of the ingot varies by no more than 15%, wherein controlling the dopant concentration of the inner melt zone includes using a model to predict the dopant concentration of the melt in the inner melt zone based at least in part on diffusion of the dopant between the inner melt zone and the outer melt zone.

2. The method of claim 1, wherein controlling the dopant concentration of the inner melt zone includes:
calculating an initial amount of dopant to be added to the melt;
adding the initial amount of dopant to the melt;
calculating a dopant feed rate for dopant to be supplied to the melt during growth of the ingot; and
adding dopant to the melt according to the dopant feed rate, wherein the initial amount of dopant and the dopant feed rate are calculated using the model to predict the dopant concentration of the melt in the inner melt zone.

3. The method of claim 2, further comprising determining a mass transfer coefficient for dopant within the melt, wherein calculating the dopant feed rate includes calculating the dopant feed rate based on the determined mass transfer coefficient.

4. The method of claim 2, further comprising determining a mass transfer coefficient for dopant within the melt, wherein calculating the initial amount of dopant includes calculating the initial amount of dopant based on the determined mass transfer coefficient.

5. The method of claim 2, wherein adding the initial amount of dopant includes adding the initial amount of dopant only after crystal growth is initiated.

6. The method of claim 5, wherein adding the initial amount of dopant includes adding the initial amount of dopant to the outer melt zone only after crystal growth is initiated.

7. The method of claim 2, wherein the initial amount of dopant is added to the outer melt zone during formation of at least one of the crown region, the neck region, the shoulder region, and the body region.

8. The method of claim 7, wherein adding the initial amount of dopant includes adding the initial amount of dopant in multiple doses, wherein each dose is added at a different time.

9. The method of claim 1, wherein controlling the dopant concentration of the inner melt zone further includes using a model to predict the dopant concentration within the inner melt zone based at least in part on evaporation of the dopant from the melt, segregation of the dopant from the ingot being grown, and convective mass transfer between the inner melt zone and the outer melt zone.

10. The method of claim 1, wherein the ingot is a first ingot, the method further comprising:
removing the first ingot from the melt; and
growing a second ingot from the melt such that the second ingot has a body region with an axial length of at least 1,000 mm, wherein controlling the dopant concentration of the inner melt zone includes controlling the dopant concentration of the inner melt zone such that the resistivity over at least 500 mm of the axial length of the second ingot varies by no more than 15%.

11. The method of claim 1, wherein the dopant is selected from the group consisting of arsenic, antimony, phosphorous, and indium.

12. The method of claim 1, wherein the dopant includes indium.

13. The method of claim 1, further comprising feeding polycrystalline silicon material to the outer melt zone while the ingot is being grown.

14. The method of claim 1, wherein the dopant includes an N-type dopant selected from the group consisting of phosphorus, arsenic, and antimony, and a P-type dopant selected from the group consisting of boron, aluminum, gallium and indium.

15. The method of claim 14, wherein the dopant further includes germanium.

16-22. (canceled)

23. A single crystal silicon ingot grown by a continuous Czochralski method comprising a constant diameter region, an axial length as measured from a seed end of the constant diameter region to a terminal end of the constant diameter region, and an electrically active dopant selected from the group consisting of arsenic, antimony, red phosphorous, and indium, wherein the axial length of the constant diameter region is at least 1,000 mm long and further wherein the resistivity over at least 500 mm of the axial length varies by no more than 15%.

24. The ingot of claim 23, wherein the resistivity over at least 500 mm of the axial length varies by no more than 10%.

25. The ingot of claim 23, wherein the resistivity over at least 500 mm of the axial length varies by no more than 5%.

26. The ingot of claim 23, wherein the axial length of the constant diameter region is at least 1,500 mm long, and the resistivity over at least 1,000 mm of the axial length varies by no more than 15%.

27. The ingot of claim 26, wherein the resistivity over at least 1,000 mm of the axial length varies by no more than 10%.

28. The ingot of claim 27, wherein the resistivity over at least 1,000 mm of the axial length varies by no more than 5%.

29. The ingot of claim 23, wherein the dopant is antimony, and the constant diameter region has a mean resistivity of no more than 30 milliohm-centimeters.

30. The ingot of claim 23, wherein the constant diameter region has a mean resistivity of no more than 10 milliohm-centimeters.

31. The ingot of claim 23, wherein the dopant is indium, and the resistivity over at least 1,500 mm of the axial length varies by no more than 7%.

32. The ingot of claim 23, wherein the constant diameter region has a diameter of at least 200 mm.

33. The ingot of claim 32, wherein the constant diameter region has a diameter of at least 300 mm.

34. A slug sliced from the ingot of claim 23.

35-58. (canceled)

59. The method of claim 2, wherein adding the initial amount of dopant includes adding the initial amount of dopant to the outer melt zone.

60. The method of claim 2, wherein adding the initial amount of dopant includes adding the initial amount of dopant to a transition melt zone between the inner melt zone and the outer melt zone.

61-63. (canceled)

64. The method of claim 10, the method further comprising:
growing multiple ingots from the melt such that each ingot has a body region with an axial length of at least 1,000 mm, wherein controlling the dopant concentration of the inner melt zone includes controlling the dopant concentration of the inner melt zone such that the resistivity over at least 500 mm of the axial length of each ingot varies by no more than 15%.
